(19) United States
(12) Patent Application Publication
(10) Pub. No.: US 2025/0148328 A1
(43) Pub. Date: May 8, 2025

(54) LASER ANNEALING QUANTUM DEVICES USING VARIABLE THERMAL PROFILES

(71) Applicant: International Business Machines Corporation, Armonk, NY (US)

(72) Inventors: Russell A. Budd, North Salem, NY (US); Eric Zhang, Sleepy Hollow, NY (US); Jared Barney Hertzberg, Yorktown Heights, NY (US); Jason S. Orcutt, Katonah, NY (US); Sami Rosenblatt, White Plains, NY (US); James B Hannon, Mahopac, NY (US); Yves Martin, Ossining, NY (US); Bucknell C. Webb, Ossining, NY (US)

(21) Appl. No.: 18/387,033

(22) Filed: Nov. 4, 2023

(51) Int. Cl. G02B 27/28; G02B 21/00; G02B 27/30; H10N 60/12

(52) U.S. Cl. CPC G06N 10/00; H01L 21/02; H10N 60/80

(57) ABSTRACT

A method comprises performing a pattern recognition process to determine a geometry of a superconducting quantum device comprising one or more Josephson junctions, determining, based on the geometry determined by the pattern recognition process, a laser beam illumination pattern for laser annealing the one or more Josephson junctions of the superconducting quantum device, and configuring a laser microscope to generate the laser beam illumination pattern.

### BACKGROUND

This disclosure relates generally to techniques for tuning Josephson junction devices and, in particular, laser annealing techniques for tuning junction resistances of Josephson junctions. A quantum computing system can be implemented using superconducting circuit quantum electrodynamics (cQED) architectures that are constructed using quantum circuit components such as, e.g., superconducting quantum bits (e.g., fixed-frequency transmon quantum bits), superconducting quantum interference devices (SQUIDs), and other types of superconducting devices which comprise Josephson junction devices. In particular, superconducting quantum bits (qubits) are electronic circuits which are implemented using components such as superconducting tunnel junction devices (e.g., Josephson junctions), inductors, and/or capacitors, etc., and which behave as quantum mechanical anharmonic (non-linear) oscillators with quantized states, when cooled to cryogenic temperatures. A fixed-frequency qubit, such as a transmon qubit, has a transition frequency (denoted f₀₁) which corresponds to an energy difference between a ground state |0) and a first excited state |1) of the qubit. It is known that the transition frequency f₀₁ of a qubit can be estimated from the resistance (denoted R_{J}) of the Josephson junction of the qubit.

A solid-state quantum processor can include multiple superconducting qubits that are arranged in a given lattice structure (e.g., square lattice, heavy hexagonal lattice) to enable quantum information processing through quantum gate operations (e.g., single-qubit gate operations and multi-qubit gate operations) in which quantum information is generated and encoded in computational basis states (e.g., |0) and |1)) of single qubits, superpositions of the computational basis states of single qubits, and/or entangled states of multiple qubits. Continuing technological advances in quantum processor design are enabling the rapid scaling of both the physical number of superconducting qubits and the computational capabilities of quantum processors. Indeed, while current state-of-the art quantum processors have greater than 50 qubits, it is anticipated that future quantum processors will have a much larger number of qubits, e.g., on the order of hundreds or thousands of qubits, or more.

Scaling the number of qubits (e.g., fixed frequency transmon qubits) in a qubit lattice, while maintaining high-fidelity quantum gate operations, remains a key challenge for quantum computing. For example, as superconducting quantum processors scale to larger numbers of qubits, frequency crowding within a qubit lattice becomes increasingly problematic since the transition frequencies of the qubits need to be precisely controlled to minimize gate errors that can arise from lattice frequency collisions (e.g., improper detuning between superconducting qubits can reduce the fidelity of multi-qubit gate entanglement operations). Due to semiconductor processing variabilities, however, the transition frequencies of superconducting qubits as fabricated can deviate from design targets.

In this regard, laser annealing techniques can be used to adjust qubit frequencies post-fabrication and thereby selectively tune fixed-frequency qubits of a given qubit lattice into desired frequency patterns. In particular, laser annealing techniques can be utilized to increase collision-free yield of fixed-frequency qubit lattices by selectively trimming (i.e., tuning) individual qubit frequencies, post-fabrication, by enabling localized thermal annealing of the Josephson junctions of the qubits to thereby adjust and stabilize the junction resistance R_{J} of the respective Josephson junctions (and correspondingly, the respective qubit transition frequencies f₀₁) with high precision. The tuning of qubit transition frequencies through laser annealing, however, is non-trivial due to, e.g., inherent variabilities of the laser anneal process itself and/or the equipment that is utilized to perform such laser annealing, post fabrication, to tune the qubit transition frequencies in a given qubit lattice. In addition, various types of superconducting quantum devices and structures (e.g., flux-tunable qubits, flux qubits and other multiple-junction qubits such as the tunable-coupler qubit and fluxonium qubit, as well as flux-tunable couplers to mediate interactions between qubits for entanglement gate operations, as well as parametric quantum-circuit devices such as Josephson ring modulators and traveling-wave parametric amplifiers etc.) having different numbers and geometric configurations of Josephson junctions (e.g., single Josephson junctions, or multiple Josephson junctions) can be challenging to laser tune in instances where a laser annealing system is not configured to effectively laser tune a wide variety of superconducting quantum devices and structures.

### SUMMARY

Exemplary embodiments of the disclosure include techniques for laser annealing quantum devices having variable geometries of Josephson junctions.

For example, an exemplary embodiment includes a method which comprises performing a pattern recognition process to determine a geometry of a superconducting quantum device comprising one or more Josephson junctions, determining, based on the geometry determined by the pattern recognition process, a laser beam illumination pattern for laser annealing the one or more Josephson junctions of the superconducting quantum device, and configuring a laser microscope to generate the laser beam illumination pattern.

Advantageously, the exemplary techniques are configured to generate a wide range of different laser beam illumination patterns that are configured to laser anneal various geometries (e.g., different numbers and layouts) of Josephson junctions of various types of superconducting quantum devices.

In another exemplary embodiment, as may be combined with the preceding paragraphs, determining the laser beam illumination pattern comprises determining a target thermal profile for laser annealing the one or more Josephson junctions of the superconducting quantum device, and selecting a laser beam illumination pattern which corresponds to the target thermal profile.

In another exemplary embodiment, as may be combined with the preceding paragraphs, selecting a laser beam illumination pattern which corresponds to the target thermal profile comprises accessing a database comprising the plurality of thermal profiles and corresponding laser beam illumination patterns, matching a thermal profile in the database with the target thermal profile, and selecting a laser beam illumination pattern in the database which corresponds to the matching thermal profile.

In another exemplary embodiment, as may be combined with the preceding paragraphs, determining the laser beam illumination pattern comprises accessing a database comprising a plurality of template device geometries and corresponding laser beam illumination patterns, matching the determined geometry of the superconducting quantum device to a template device geometry in the database, selecting a laser beam illumination pattern in the database which corresponds to the matching template device geometry.

In another exemplary embodiment, as may be combined with the preceding paragraphs, configuring the laser microscope to generate the laser beam illumination pattern comprises configuring the laser microscope to generate a collimated laser beam having a target beam diameter, and configuring the laser microscope to select one of a plurality of different diffractive optical elements to place in an optical path of the collimated laser beam to split the collimated laser beam into a plurality of laser beams.

In another exemplary embodiment, as may be combined with the preceding paragraphs, configuring the laser microscope to generate the laser beam illumination pattern comprises configuring the laser microscope to generate a collimated laser beam having a target beam diameter, configuring the laser microscope to select one of a plurality of different spiral phase plates to place in an optical path of the collimated laser beam to generate an annular laser beam based on the collimated laser beam, and configuring the laser microscope to select one of a plurality of different diffractive optical elements to place in an optical path of the annular laser beam to split the annular laser beam into a plurality of annular laser beams.

In another exemplary embodiment, as may be combined with the preceding paragraphs, configuring the laser microscope to generate the laser beam illumination pattern comprises configuring the laser microscope to generate a collimated laser beam having a target beam diameter, and configuring the laser microscope to select one of a plurality of different optical attenuation elements to place in an optical path of the collimated laser beam to adjust a laser illumination intensity of the collimated laser beam based on the selected optical attenuation element.

Another exemplary embodiment includes a method which comprises aligning a superconducting quantum device which comprises a geometry of one or more Josephson junctions, in a field of view of a laser microscope apparatus, generating, by operation of the laser microscope apparatus, a laser beam illumination pattern based on the geometry of the one or more Josephson junctions of the superconducting quantum device, adjusting, by operation of the laser microscope apparatus, an illumination intensity of the laser beam illumination pattern, and exposing, by operation of the laser microscope apparatus, the superconducting quantum device with the laser beam illumination pattern for a given anneal time to laser anneal the one or more Josephson junctions of the superconducting quantum device.

Another exemplary embodiment includes an apparatus which comprises a collimator, a switchable attenuator device, and a switchable diffractive optical element device. The collimator is configured to receive a laser beam through an optical fiber coupled to an optical source and to generate a collimated laser beam. The switchable attenuator device comprises a plurality of attenuation elements, and is configured to selectively position a given attenuation element in an optical path of the collimated laser beam to adjust a laser illumination intensity of the collimated laser beam based on the given attenuation element. The switchable diffractive optical element device comprises a plurality of diffractive optical elements, and is configured to selectively position a given diffractive optical element in the optical path of the collimated laser beam to split the collimated laser beam into a plurality of laser beams.

Other embodiments will be described in the following detailed description of exemplary embodiments, which is to be read in conjunction with the accompanying figures.

### BRIEF DESCRIPTION OF THE DRAWINGS

FIG. 1 schematically illustrates a laser annealing system for laser tuning superconducting quantum devices, according to an exemplary embodiment of the disclosure.

FIG. 2 schematically illustrates a laser unit according to an exemplary embodiment of the disclosure.

FIG. 3A schematically illustrates a laser annealing apparatus comprising a modular laser microscope unit, according to an exemplary embodiment of the disclosure.

FIG. 3B is a perspective view of a modular optical scope unit, according to an exemplary embodiment of the disclosure.

FIG. 4 schematically illustrates a laser annealing system, according to another exemplary embodiment of the disclosure.

FIG. 5A schematically illustrates a method for generating a laser beam illumination pattern using laser microscope unit, according to an exemplary embodiment of the disclosure.

FIG. 5B schematically illustrates a method for controlling laser power in a laser beam path of a laser microscope unit, according to an exemplary embodiment of the disclosure.

FIG. 5C schematically illustrates a method for adjusting a laser beam spot size using a variable beam expander of a laser microscope unit, according to an exemplary embodiment of the disclosure.

FIG. 5D schematically illustrates a method for generating different laser beam illumination patterns using a laser microscope unit, according to an exemplary embodiment of the disclosure.

FIG. 5E schematically illustrates a method for generating different laser beam illumination patterns using a laser microscope unit, according to an exemplary embodiment of the disclosure.

FIG. 6A schematically illustrates a process for generating a dual laser beam spot pattern having Gaussian laser beam spots, according to an exemplary embodiment of the disclosure.

FIG. 6B schematically illustrates a process for generating a dual laser beam spot pattern having annular laser beam spots, according to an exemplary embodiment of the disclosure.

FIG. 7A schematically illustrates a process for laser annealing a quantum device using a laser beam illumination pattern, according to an exemplary embodiment of the disclosure.

FIG. 7B schematically illustrates a process for laser annealing a quantum device using a laser beam illumination pattern, according to another exemplary embodiment of the disclosure.

FIG. 7C schematically illustrates a process for laser annealing a quantum device using a laser beam illumination pattern, according to another exemplary embodiment of the disclosure.

FIG. 7D schematically illustrates a process for laser annealing a quantum device using a laser beam illumination pattern, according to another exemplary embodiment of the disclosure.

FIG. 7E schematically illustrates a process for laser annealing a quantum device using a laser beam illumination pattern, according to another exemplary embodiment of the disclosure.

FIG. 7F schematically illustrates a process for laser annealing a quantum device using a laser beam illumination pattern, according to another exemplary embodiment of the disclosure.

FIG. 7G schematically illustrates a process for laser annealing a quantum device using a laser beam illumination pattern, according to another exemplary embodiment of the disclosure.

FIG. 7H schematically illustrates a process for laser annealing a quantum device using a laser beam illumination pattern, according to another exemplary embodiment of the disclosure.

FIG. 7I schematically illustrates a process for laser annealing a quantum device using a laser beam illumination pattern, according to another exemplary embodiment of the disclosure.

FIG. 8A schematically illustrates different geometries and layouts of Josephson junctions, which may comprise portions of superconducting quantum devices, and which can be laser annealed using different laser beam illumination patterns, according to exemplary embodiments of the disclosure.

FIG. 8B schematically illustrates superconducting quantum devices having different geometries and layouts of Josephson junctions, which can be laser annealed using different laser beam illumination patterns, according to exemplary embodiments of the disclosure.

FIG. 9A schematically illustrates an exemplary superconducting quantum device having multiple Josephson junctions which can be concurrently laser annealed using a laser beam illumination pattern, according to an exemplary embodiment of the disclosure.

FIG. 9B schematically illustrates a process for laser annealing the exemplary superconducting quantum device of FIG. 9A in two sequential iterations using a laser beam illumination pattern comprising three laser beam spots that are linearly arranged, according to an exemplary embodiment of the disclosure.

FIG. 10A illustrates a flow diagram of a method for configuring a laser microscope to generate a laser beam illumination pattern for performing a laser annealing operation, according to an exemplary embodiment of the disclosure.

FIG. 10B illustrates a flow diagram of a method for configuring a laser microscope to adjust a laser illumination intensity for different operation conditions, according to an exemplary embodiment of the disclosure.

FIG. 11 illustrates a flow diagram of a method for automated selection of a laser beam illumination pattern for laser tuning a quantum device, according to an exemplary embodiment of the disclosure.

FIG. 12A illustrates a flow diagram of a method for automatically aligning a laser beam illumination pattern to a field of view of a laser microscope unit, according to an exemplary embodiment of the disclosure.

FIG. 12B schematically illustrates a method for automated alignment of a laser beam illumination pattern to a Josephson junction of a quantum device, according to an exemplary embodiment of the disclosure.

FIG. 13A illustrates a flow diagram of an automated process 300 for selecting a laser beam illumination pattern for laser annealing a quantum device based on a target thermal profile, according to an exemplary embodiment of the disclosure.

FIG. 13B schematically illustrates a process for selecting a laser beam illumination pattern for laser annealing a quantum device based on a target thermal profile, according to an exemplary embodiment of the disclosure.

FIG. 14A illustrates a flow diagram of a method for automatically selecting a target laser beam illumination pattern for laser annealing a quantum device based on a matching template device geometry, according to an exemplary embodiment of the disclosure.

FIG. 14B schematically illustrates a process for automatically selecting a target laser beam illumination pattern for laser annealing a quantum device based on a matching template device geometry, according to an exemplary embodiment of the disclosure

FIG. 15 illustrates a flow diagram of a method that is implemented by a laser unit for optically coupling a laser beam to an optical fiber, according to an exemplary embodiment of the disclosure.

FIG. 16 illustrates a flow diagram of a method for monitoring a power level and beam quality of a laser beam that is generated by a laser unit, according to an exemplary embodiment of the disclosure.

FIG. 17A graphically illustrates a bidirectional tuning curve for laser tuning Josephson junctions, according to an exemplary embodiment of the disclosure.

FIG. 17B illustrates a flow diagram of a calibration process for obtaining calibration data for use in generating tuning curves and associated calibration data for bidirectional laser tuning of Josephson junctions, according to an exemplary embodiment of the disclosure.

FIG. 18 illustrates a flow diagram of a method for tuning Josephson junctions, according to an exemplary embodiment of the disclosure.

FIG. 19 schematically illustrates an exemplary architecture of a computing environment for implementing a control system that is configured to control a laser annealing system for tuning Josephson junctions, according to an exemplary embodiment of the disclosure.

### DETAILED DESCRIPTION

Exemplary embodiments of the disclosure will now be described in further detail with regard to laser annealing apparatus and techniques that enable laser annealing quantum devices having variable geometries of Josephson junctions. It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs. In addition, the terms “about” or “substantially” as used herein with regard to, e.g., percentages, ranges, etc., are meant to denote being close or approximate to, but not exactly. For example, the term “about” or “substantially” as used herein implies that a small margin of error may be present, such as 1% or less than the stated amount.

It is to be further understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

Further, the term “quantum chip” as used herein is meant to broadly refer to any device which comprises qubits and possibly other quantum devices. For example, a quantum chip can be semiconductor die which comprises an array (lattice) of qubits, which is fabricated on a wafer comprising multiple dies, and which can be diced (cut) from the wafer using a die singulation process to provide a singulated die. In some instance, a quantum chip can be a wafer with multiple semiconductor die. In the context of quantum computing, a quantum chip may comprise one or more processors for a quantum computer.

Moreover, the term “shot” as used herein denotes a laser anneal operation that is performed by applying laser power to a target element (e.g., Josephson junction) for a specified duration (anneal time) to tune the target element. In the context of exemplary embodiments of the disclosure as discussed herein, laser tuning methods are provided to tune junction resistances of Josephson junctions in a progressive and incremental manner wherein multiple “shots” are applied to a given Josephson junction to tune the junction resistance of the Josephson junction to a target junction resistance, which is to be contrasted with conventional approaches that tune a Josephson junction to a target junction resistance using only one laser shot.

The term “iterate” or “iteratively” used herein and in the context of a laser annealing process is meant to refer to the process which comprises a single “shot” along with associated control, measurement and computation by a LASIQ computer system and apparatus to determine a target anneal time and power for performing the anneal shot. A laser annealing iteration, or LASIQ iteration, therefore refers to the entire process by which a Josephson junction is measured, the anneal power and time is determined, and the anneal shot is performed. In this sense, a single iteration involves an entire sequence of the laser annealing system and apparatus as it pertains to one step of a progressive approach to a resistance target for one Josephson junction. The tuning of one junction to completion (i.e., reaching its target resistance) may therefore be said to progress “iteratively.” The term “iterative process” as used herein, is meant to generally refer to a set of iterations, as applicable to one or more qubits, or the like, comprising Josephson junctions, whereby the one or more qubits are tuned with the purpose of approaching their respective targets.

The term “progressive” or “progressively” as used herein and in the context of a laser annealing process, is meant to refer to the gradual approach of shifting a junction resistance of a Josephson junction to a respective target resistance. Such a progressive approach is a result of multiple annealing iterations, each of which include a laser shot to alter the junction resistance in the desired direction towards the target resistance. Additionally, such a progressive approach is asymptotic, in the sense that the tuning rate nominally decreases as the junction resistance of a given Josephson junction approaches nearer to its respective target resistance.

The term “adaptive” or “adaptively” as used herein and in the context of a laser annealing process, is meant to refer to the appropriate selection of laser annealing parameters, including such parameters as laser annealing time and annealing power, as it pertains to a laser shot, to allow the Josephson junction resistances to monotonically and asymptotically approach their respective resistance targets. The adaptive nature of the laser annealing iterations is achieved using methods described herein, whereby the laser anneal time and power are selected based on historical reconstruction of the tuning progression of the specific junction. The methods described herein account for the rate of historical tuning of the specific junction being tuned, thereby mitigating the risk of missing resistance targets (e.g., by using laser shots that have excess time such that the junction resistance is tuned beyond the desired resistance target).

The term “round-robin” as used herein and in the context of a laser annealing process for tuning the Josephson junctions of qubits, is meant to refer to a tuning process in which the Josephson junctions of, e.g., all qubits on a multi-qubit device undergo the laser annealing process in succession, and which may be followed by another round-robin or multiple round-robins in succession. Such round-robins may be continuously performed until all qubits on the multi-qubit device reach their respective targets. For example, a singulated quantum chip may comprise a number of qubit devices (e.g., 100 qubits, denoted Q1, Q2, Q3, . . . , Q100) comprising Josephson junctions. In an exemplary embodiment of a tuning method, Q1 will first be tuned with one or more annealing iterations, as desired. The process will proceed to Q2, where one or more annealing iterations may be performed, as desired. The process will then proceed to Q3, etc., until finally Q100 is tuned with one or more annealing iterations, as desired. The entire process from Q1 to Q100 is defined as one round-robin. After this first round-robin, the process may return to Q1, and will repeat again until Q100 is reached. The process of successive round-robins may provide a means of time control and delay between iterations or sets of iterations, such that the Josephson junctions may be permitted to relax to their final junction resistances prior to the next annealing iteration or set of iterations.

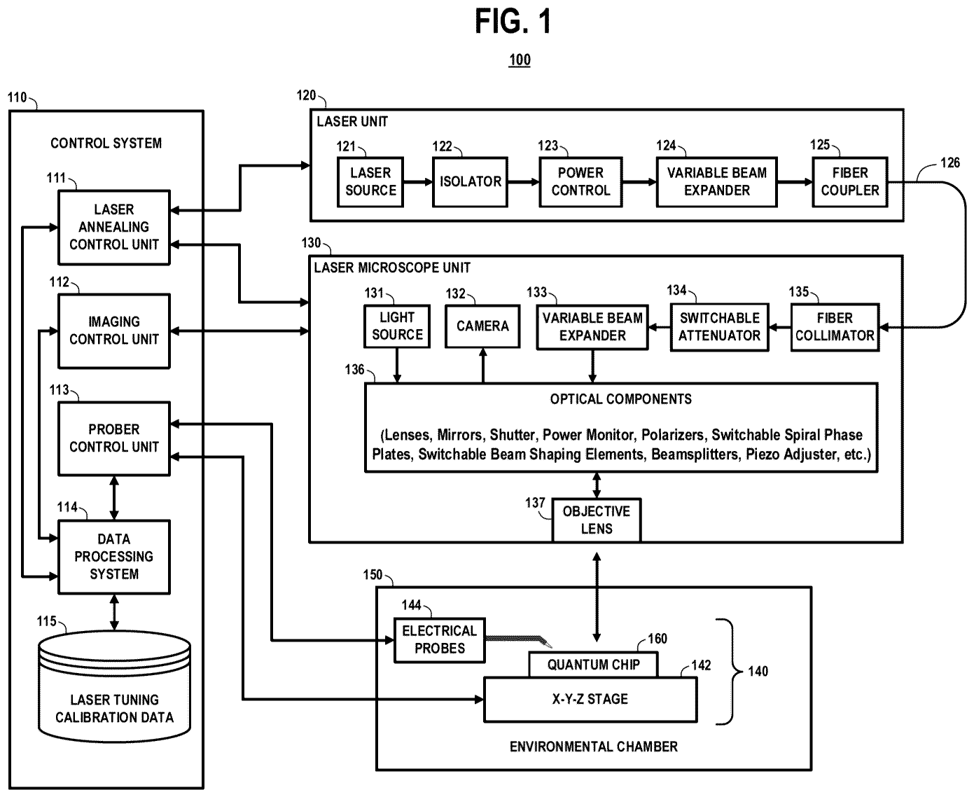

FIG. 1 schematically illustrates a laser annealing system 100 for laser tuning superconducting quantum devices, according to an exemplary embodiment of the disclosure. In some embodiments, the laser annealing system 100 is configured to implement LASIQ (Laser Annealing of Stochastically Impaired Qubits) tuning methods for laser annealing of Josephson junctions of qubits, post-fabrication, to adjust and stabilize the junction resistances Ryand thereby selectively tune the individual qubit frequencies via laser thermal annealing of the respective Josephson junctions. As schematically shown in FIG. 1, the laser annealing system 100 comprises a control system 110, a laser unit 120, an optical fiber 126, a laser microscope unit 130, a prober unit 140, and optional environmental chamber 150.

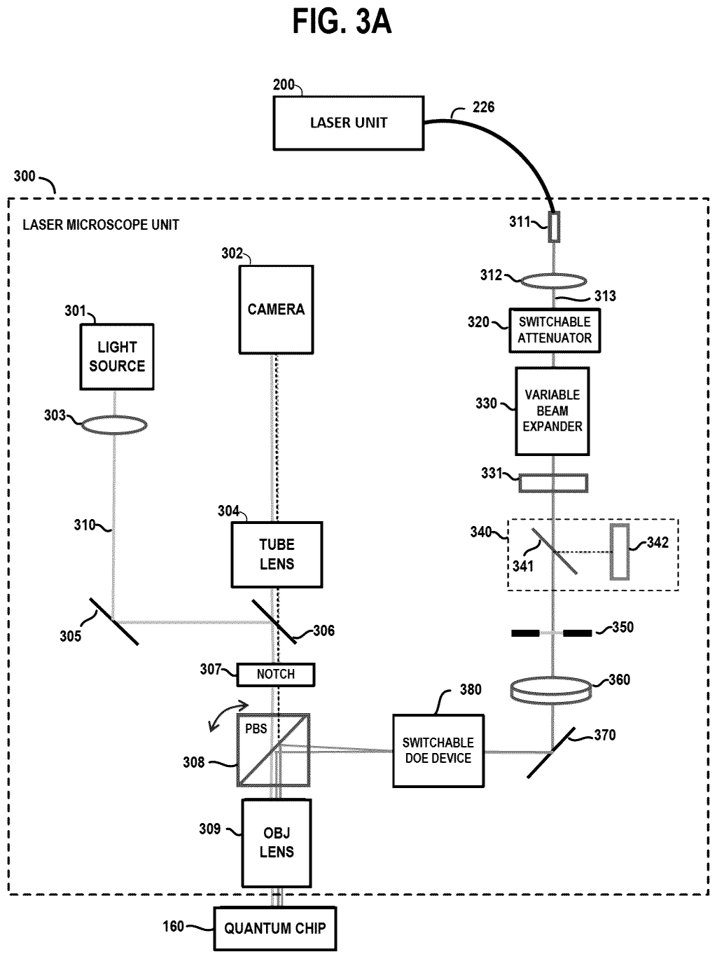

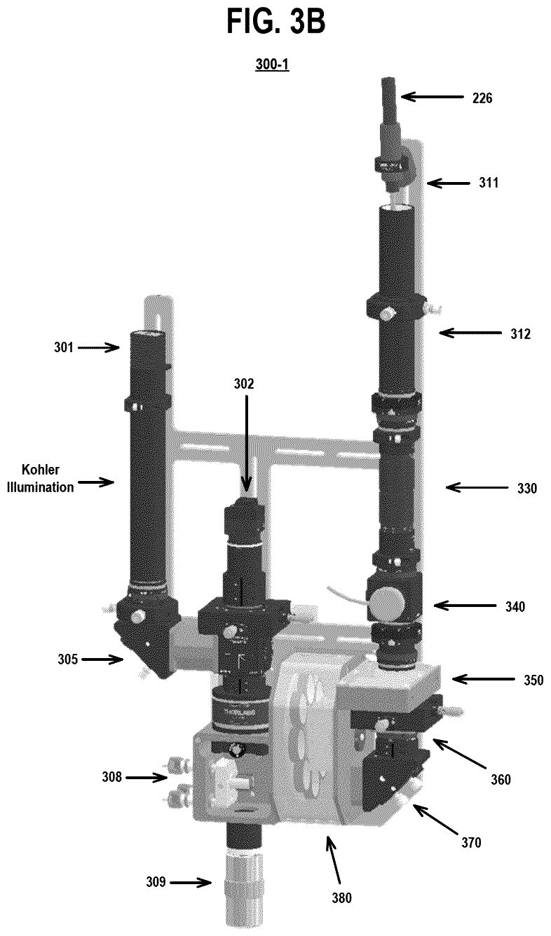

The control system 110 comprises a laser annealing control unit 111, an imaging control unit 112, a prober control unit 113, a data processing system 114, and a database of laser tuning calibration data 115. In some embodiments, the laser unit 120 comprises a laser source 121, an isolator 122, a laser power control block 123, a variable beam expander 124, and a fiber coupler 125. In some embodiments, the laser microscope unit 130 comprises a light source 131, a camera 132, a variable beam expander 133, a switchable attenuator device 134, a fiber collimator 135, a plurality of optical components 136, and an objective lens 137. The optical components 136 comprise various types of optical component and elements including, but not limited to, lenses, mirrors, an electronic shutter, a power monitor, polarizers, variable spiral phase plates, variable beam shaping elements (e.g., different diffractive optical elements), beam splitters, and piezoelectric actuators, etc. An exemplary architecture of the laser microscope unit 130 will be discussed in further detail below in conjunction with FIG. 3A.

The prober unit 140 comprises an X-Y-Z stage 142, and electrical probes 144. A quantum chip 160 (or any other similar device under test) can be mounted to the X-Y-Z stage. In some embodiments, the quantum chip 160 comprises a lattice of superconducting qubits, where each superconducting qubit comprises at least one respective Josephson junction which can be annealed using the laser annealing system 100 to tune the junction resistance and, thus, tune the transition frequency of the superconducting qubit, post-fabrication. The laser microscope unit 130 is configured to generate a wide variety of laser beam illumination patterns and thermal profiles for laser tuning various types of superconducting quantum devices and structures (e.g., SQUID-based devices, flux-tunable qubits, flux-tunable couplers to mediate interactions between qubits for entanglement gate operations, etc.) with different numbers and geometric configurations of Josephson junctions (e.g., single Josephson junctions, or multiple Josephson junctions).

In some embodiments, the laser unit 120 and the laser microscope unit 130 comprise modular units that are coupled together via the optical fiber 126. In some embodiments, the optical fiber 126 comprises a single-mode (SM) polarization-maintaining (PM) optical fiber, which is configured to preserve a linear polarization of linearly polarized light that is injected into the optical fiber 126 by the laser unit 120 and propagated to the laser microscope unit 130. The laser microscope unit 130 can be integrated onto the prober unit 140 (e.g., a wafer-scale prober). In this regard, in some embodiments, the laser unit 120, the laser microscope unit 130, and the prober unit 140 can be physically coupled/attached to each other to form an integrated laser annealing apparatus which is configured to perform laser anneal operations for tuning junction resistances of Josephson junctions, as well as performing in-situ junction resistance measurements, under the control of the control system 110. In some embodiments, the control system 110 is operatively/communicatively coupled to the laser unit 120, the laser microscope unit 130, and the prober unit 140 via wires and/or wirelessly. The control system 110 comprises hardware and/or software for automated control of various operations of the laser unit 120, the laser microscope unit 130, and the prober unit 140 of the laser annealing system 100.

The laser unit 120 is configured to generate a laser beam that is transmitted to the laser microscope unit 130 via the optical fiber 126, wherein the laser microscope unit 130 is configured to generate a wide variety of laser beam illumination patterns comprises a single or multi-spot geometrics to laser anneal Josephson junctions of superconducting quantum devices having variable Josephson junction geometries. In some embodiments, the laser source 121 comprises a solid-state diode pump to generate laser energy, and a laser head to generate a focused laser beam from the laser energy emitted from the solid-state diode pump. In some embodiments, the diode pump comprises a 532 nanometer (nm) (frequency doubled) diode-pumped solid-state laser (e.g., a second harmonic generation (SHG) laser). In some embodiments, the power level of the laser source 121 (e.g., solid-state diode pump) can be adjusted by the control system 110. For example, the power level of the laser source 121 can be set to one of a plurality of different power level settings (e.g., lower power, medium power, high power settings). The isolator 122 is configured to provide polarization cleanup and to provide optical isolation to mitigate unwanted feedback to the laser head of the laser source 121.

The laser power control block 123 is configured to actively monitor, control, and calibrate the power level of a laser beam generated by the laser source 121. In some embodiments, the lower power control block 123 generates electrical signal that is indicative of the laser power level, and the electrical signal is feedback to the control system 110 (e.g., the laser annealing control unit 111), and the control system 110 generates control signals that are applied to the laser power control block 123 to adjustably control a laser power level for laser tuning Josephson junctions. More specifically, in some embodiments, the power level of the laser beam can be coarsely adjusted by controlling the power output of the laser source 121, while the power level of the laser beam can be finely adjusted by operation of the laser power control block 123.

The variable beam expander 124 is configured to adjust a diameter of the laser beam that is input to the fiber coupler 125 to adjust a focus (e.g., focal point) of a laser beam by the fiber coupler 125 to optimize a coupling of the laser beam into the optical fiber 126, using optical component and techniques as discussed in further detail below. In some embodiments, the optical fiber 126 comprises a single-mode polarizing-maintaining (SM PM) optical fiber 126 which is configured to maintain a polarization of the laser beam that is generated by the laser unit 120.

In the laser microscope unit 130, the fiber collimator 135 (e.g., collimating lens) is configured to transform the laser light which is output from the optical fiber 126 into a free-space collimated laser beam. In some embodiments, the laser microscope unit 130 comprises a power monitor which comprises, e.g., a beam sampler (e.g., beam splitter) and photodiode, to monitor the power of the collimated laser beam to enable precise exposure control downstream from the power control/adjustment mechanisms provided by the laser unit 120.

The switchable attenuator device 134 comprises a plurality of attenuation elements. The switchable attenuator device 134 is configured to selectively position a given attenuation element in an optical path of the collimated laser beam generated by the fiber collimator 135 to adjust a laser illumination intensity of the collimated laser beam based on the given attenuation element. The attenuation elements are configured to have different optical densities for achieving different attenuation levels of the laser beam illumination intensity.

The variable beam expander 133 is configured to adjust a diameter of the collimated laser beam. As explained in further detail below the variable beam expander 133 is configured to adjust the beam diameter of the collimated laser beam, which results in adjusting the diameters of the image plane focused laser spots that are incident on a surface of the quantum chip 160 to laser anneal Josephson junctions of superconducting quantum devices formed on the surface of the quantum chip 160.

The additional optical components 136 of the laser microscope 130 include an electronic shutter that is operated under control of, e.g., the laser annealing control unit 111 of the control system 110, to control the time duration of laser exposure when annealing a given Josephson junction. For example, the electronic shutter can be opened for a given duration of time when annealing a target Josephson junction to allow annealing laser beams to be projected onto the quantum chip 160 in proximity to the target Josephson junction, and then automatically close after the given duration of time. In this regard, the laser power level and the pulse duration (laser exposure) can be controlled to achieve a desired change (e.g., decrease) in the resistance of the annealed Josephson junction.

The additional optical components 136 of the laser microscope 130 further include switchable laser beam shaping elements (e.g., diffractive optical elements (DOEs)) having various diffraction gratings that are configured to split a single laser beam into two or more laser beams with slightly different angles relative to one another. The diffractive optical elements include, for example, diffractive beam splitters that are configured to split a single laser beam into several beams (diffraction orders) in a predefined configuration (e.g., dual laser spots, three laser spots, a quad-spot pattern, etc.). A diffractive beam splitter comprises a holographic optical element that imparts a precise angle (e.g., a 0.5 degree shift) to an incoming laser beam in plus and minus angular directions relative to a reference plane, to thereby generate a plurality of outgoing laser beams. In some embodiments, the switchable DOE components include one or more 2-by-2 diffractive beam splitters, which are configured to splits a single collimated laser beam into four separate laser beams, which results in a final quad-spot illumination pattern that is projected onto the surface of the quantum chip 160 at a target location, exemplary embodiments of which will be discussed in further detail below. The switchable DOE components comprise a variety of diffractive beam splitters that the can selected for use to generate any desired number (e.g., 2, 3, 5, 6, etc.) of laser beams with defined illumination patterns tailored to different applications.

The laser microscope unit 130 implements the light source 131 and the camera 132 for illuminating and viewing target features (e.g., qubits and corresponding Josephson junctions) on the surface of the quantum chip 160 within a given field of view (FOV) of the laser microscope unit 130. In some embodiments, the light source 131 comprises any suitable light generating device including one or more light emitting diodes (LEDs) with desired photonic wavelengths, a monochromatic light source, etc. The light source 131 together with some of the optical components 136 in the optical viewing path implement Kohler illumination to create uniform illumination of the target features in the FOV of the laser microscope unit 130 and to ensure that an image of the light source 131 is not visible in the resulting images captured by the camera 132.

In some embodiments, the camera 132 comprises a charge-coupled device (CCD) image sensor, or an infrared (IR) complementary metal oxide semiconductor (CMOS) image sensor. The camera 132 is utilized to capture images of a target region on the surface of the quantum chip 160 to facilitate, e.g., aligning the electrical probes 144 to contact electrodes when performing in-situ Josephson junction resistance measurements, aligning the laser beam pattern onto the target region when performing laser annealing operations, etc. For example, in some embodiments, the Josephson junction of a given qubit is aligned to the center of the FOV of the laser microscope unit 130 using pattern recognition to, e.g., a Josephson junction template image. Also, in some embodiments, more than one camera may be used in parallel, by splitting the image path using a beam splitter and using, for example, an IR CMOS camera in addition to a visible wavelength camera, which may be used for process monitoring (e.g., a wide FOV for inspection, process tracking, or the like).

The objective lens 137 is the lens that is located closest to the device under test (quantum chip 160) and serves to provide the base magnification for generating a magnified image that is viewed by the camera 132, and to project the annealing laser beam pattern (e.g., quad-spot pattern) onto the surface of the quantum chip 160. In some embodiments, the objective lens 137 comprises a long working distance (WD) objective lens. In an exemplary non-limiting embodiment, the objective lens 137 (together with an optional second objective lens) is configured to condense the laser beams and multi-spot pattern by 4×, while providing 20× image magnification.

The prober unit 140 is configured to automatically move the position of the quantum chip 160 during a laser annealing process to align a target Josephson junction or group of junctions of a given qubit or quantum structure within the FOV of the laser microscope unit 130 to perform an in-situ Josephson junction resistance measurement and a laser anneal of the target Josephson junctions. In particular, the quantum chip 160 is mounted to the automated X-Y-Z stage 142 which is controllably moved in three dimensions to align features of the quantum chip 160 within the FOV of the laser microscope unit 130 and enable contact between the electrical probes 144 and contact pads on the quantum chip 160. For example, in some embodiments, during a laser anneal process, a target Josephson junction of a given qubit is aligned to the center of the FOV of the laser microscope unit 130 using an automated pattern recognition process in which features of an image captured by the camera 132 are automatically aligned to corresponding features of a template image to ensure proper positioning of the target Josephson junction and associated contact pads. In particular, an alignment process is performed to ensure accurate registration between the contact pads of the target Josephson junction and the electrical probes 144 when performing an in-situ Josephson junction resistance measurement. In addition, an alignment process is performed to ensure a proper alignment of the target Josephson junction and a laser spot pattern when performing a laser anneal operation.

As noted above, the electrical probes 144 are implemented to perform in-situ Josephson junction resistance measurements during a laser anneal process. In particular, in-situ Josephson junction resistance measurements are performed in between laser annealing operations (shots) to track the tuning progress of the Josephson junctions of the qubits during a multi-step (i.e., iterative) anneal process in which the Josephson junctions are progressively tuned. In some embodiments, the electrical probes 144 comprise two pairs of probes, which are configured to perform a 4-wire resistance measurement (or Kelvin resistance measurement) to more precisely measure the junction resistance of a Josephson junction and mitigate the impact of finite contact resistance on the junction resistance measurement. In general, a 4-wire (Kelvin) resistance measurement involves determining the resistance of a given Josephson junction by measuring a current (I) flow through the junction as well as a voltage (V) drop across the junction, and determining the junction resistance R_{J} from Ohm's Law, i.e., R_{J}=V/I. In a similar manner, resistance measurements may be made on a combined parallel or series resistance of groups of Josephson junctions spanning the contact pads.

In some embodiments, the electrical probes 144 comprise a probe card that is mechanically mounted in a fixed position to the prober unit 140. In some embodiments, the integration of the laser microscope unit 130 and the prober unit 140 is configured to ensure that a sample imaging plane and a laser focal plane are substantially identical, while a probing plane is displaced from the sample imaging plane by a present amount, e.g., 70 microns, 80 microns, etc. In this configuration, the electrical probes 144 are fixedly displaced from the image plane, and the Z position of the X-Y-Z stage 142 (with the quantum chip 160 mounted thereon) is moved into a default contact position to make electrical contact between the electrical probes 144 and target contact pads on the quantum chip 160, to perform an in-situ Josephson junction resistance measurement. In some embodiments, the laser microscope unit 130 may also be mounted on its own X-Y-Z stage and may be additionally moved with those corresponding X, Y, and Z degrees of freedom.

In some embodiments, in order to image, electrically characterize, and anneal Josephson junctions, the X-Y-Z stage is set at various positions such that these functions may be safely and effectively performed. We herein use the terms “contact position,” “anneal position,” and “safety position” to denote various positions of the X-Y-Z stage.

By “contact position,” as used herein and in the context of laser annealing system 100, is meant to refer to the position of the X-Y-Z stage 142 such that the sample (i.e., quantum chip 160) is in mechanical and electrical contact with the probes. That is to say, the surface of the sample is substantially identical to the probing plane. In this “contact position” configuration, electrical characterization may take place, which typically involves a 4-wire (Kelvin) resistance measurement. Each annealing iteration will typically involve a junction resistance measurement, where the X-Y-Z stage 142 is brought into the “contact position” prior to subsequent annealing.

The term “anneal position,” as used herein and in the context of laser annealing system 100, is meant to refer to the Z position of the X-Y-Z stage 142 such that the surface of the sample (i.e., quantum chip 160) is at the focal plane of the laser annealing beam. In an exemplary embodiment, at the “anneal position,” the surface of the sample (i.e., quantum chip 160) is substantially identical to the imaging plane, such that both imaging and annealing occurs at the same Z position of the X-Y-Z stage 142, or stated equivalently, the sample and laser beam may be both viewed in focus simultaneously by the imaging system. Additionally, at the “anneal position,” pattern recognition and corrective alignment may take place, such that the junction is correctly centered at the FOV prior to annealing. It is also at the anneal position which visual characterization, inspection, and the like, may be performed to determine whether the chip is physically suitable for use as a chip candidate. Nominally, the “anneal position” may be chosen to be a fixed difference from the “contact position,” which is herein defined as the “separation distance,” which may be, for example, 70 microns, 80 microns, etc., and may be selected by the operator as desired.

The term “safety position,” as used herein and in the context of laser annealing system 100, is meant to refer to a large displacement of the Z position of the X-Y-Z stage 142 such that the surface of the sample (i.e., quantum chip 160) is safely displaced from the “contact position” such that the tallest surface feature of the sample will not cross the probing plane, or stated equivalently, no feature on the sample intersects the probing plane. In this way, regardless of the X-position or Y-position that is chosen on the sample, the probes suffer no risk of damage due to impact with any surface feature while the X-Y-Z stage 142 is in the “safety position.”

In an exemplary embodiment, the position of the probe card is fixed in the Z position, and the “separation distance” is selected to be 70 microns, that is, the “anneal position” is 70 microns below the “contact position.” Additionally, the “safety position” may be chosen (for example) to be 1000 microns or larger, or a value that is sufficiently larger than the height of any feature on the sample. When the apparatus is initialized, the relative positions of the sample plane, the probing plane, imaging plane and laser annealing plane are not known a priori, and any operation performed using the laser annealing system 100 may exhibit, for example, image defocusing, poor electrical contact during probing, and/or poor annealing performance. Therefore, an initialization protocol must be performed to ensure that the contact position, anneal position, and safety position is well defined.

In an exemplary embodiment, to define these positions, the X-Y-Z stage 142 may be programmed to move to a safe location, either on a test chip, an initialization chip, or the like, where a clean conducting surface (e.g., contact pads) is available under the probes. In this exemplary embodiment, a dedicated initialization chip with an array of conducting contact pads are available to safely contact the electrical probes 144. The X-Y-Z stage 142 is subsequently incremented (e.g., in 2-micron increments) in the Z position, towards the electrical probes 144, and the contact resistance is checked for each increment until a contact threshold is realized (e.g., 100 ohms, or another threshold as desired), which indicates successful contact between the sample and the probing plane, or equivalently, the sample plane and probing plane are co-located, and the X-Y-Z stage 142 is in the “contact position.” Subsequent to determining the contact position, the X-Y-Z stage 142 is lowered in the Z position by the desired 70 microns “separation distance,” such that the X-Y-Z stage 142 is in “alignment position.” However, it may be the case the image focal plane is not yet at a substantially identical position as the sample surface. In this case, the laser microscope unit may be adjusted, either manually using a Z focus adjustment, or automatically (in the case where the laser microscope is mounted on its own X-Y-Z stage, and controlled by the imaging control unit 112), such that the imaging focal plane is made substantially identical to the sample plane.

Using this protocol, the “anneal position” thus corresponds to the sample surface being in focus in the laser microscope unit 130, and both imaging and annealing may now occur at the “anneal position.” In the case where electrical measurement is desired, reliable probing may subsequently be implemented by simply incrementing the Z position of the X-Y-Z stage 142 by 70 microns (i.e., the “separation distance”), or more, as some level of overtravel is desirable for robust electrical contact. Furthermore, a “safety position” may be defined, such that when moving between qubits, or other features on the quantum chip 160, the X-Y-Z stage 142 first moves to its safety position, then moves to the X and Y-position of the desired feature, then moves to either the “anneal position” for imaging/tuning, or to the “contact position” for electrical characterization. This initialization protocol described above may be generally implemented to ensure that stage motion, imaging, annealing, and electrical measurement may be safely and reliably performed. It is to be understood that in one or more embodiments, the above initialization protocol, as well as the various X-Y-Z stage 142 positions, are actively used in the operation and calibration of laser annealing system 100. In some embodiments, the laser focal plane may be engineered as an additional degree of freedom relative to the image focal plane, and the laser beam may be focused or defocused as desired.

In some embodiments, the prober unit 140 is housed or otherwise disposed within the optional environmental chamber 150 to control an ambient environment during laser annealing, wherein different ambient environments impact the laser annealing progression differently. For example, in some embodiments, the laser annealing system 100 may comprise an environmental gas control system which is coupled to the environmental chamber 150 and which is configured to inject a mixture of one or more gases into the environmental chamber 150 to control the annealing environment. More specifically, in some embodiments, the environmental gas control system may comprise a gas dilution unit which is connected to a plurality of gas cylinders which store different gases (e.g., nitrogen, dry air, etc.), wherein the gas dilution unit can mix different gases at various concentrations and inject the mixed gases into the environmental chamber 150, as desired, to provide a given gas environment for laser annealing. In addition, the environmental gas control system comprises a vacuum system coupled to the environmental chamber 150 to evacuate anneal gases from the chamber or otherwise evacuate air from the environmental chamber 150 to perform laser annealing in a vacuum atmosphere.

Moreover, in some embodiments, a temperature control system is coupled to the X-Y-Z stage 142 (e.g., wafer chuck) to control the temperature of the X-Y-Z stage 142 on which the quantum chip 160 is mounted. The X-Y-Z stage 142 may be temperature controlled to allow high-temperature anneals (e.g., bulk anneals) or low-temperature probing for low-noise electrical resistance measurements, as well as reducing the relative contribution of substrate conductivity on the junction resistance measurement. For example, in some embodiments, the X-Y-Z stage 142 can be temperature controlled in a range of −60° C. to 300° C.

As noted above, various functions of the laser unit 120, the laser microscope unit 130, and the prober unit 140 are automatically controlled by the control system 110. In some embodiments, the laser annealing control unit 111, the imaging control unit 112, and the prober control unit 113, comprise respective hardware interfaces for interfacing with the laser unit 120, the laser microscope unit 130, and the prober unit 140, as needed, to generate and apply control signals to components of such units 120, 130, and 140, and to receive and process signals (e.g., data, measurements, feedback controls signals, etc.) received from components of such units 120, 130, and 140. The data processing system 114 comprises one or more processors that execute software programs/routines to control laser annealing, imaging, and prober operations by processing data received from the control units 111, 112, and 113 (e.g., to perform automated pattern recognition for active alignments, perform junction resistance measurement computations, etc.), and generating and outputting control signals to cause the control units 111, 112, and 113, to control the operations of the laser unit 120, the laser microscope unit 130, and the prober unit 140 in a coordinated manner, when performing laser annealing and in-situ junction resistance measurements, as discussed herein.

For example, in some embodiments, the laser annealing control unit 111 is configured to control operation of components of the laser unit 120, such as the laser source 121 and the laser power control block 123, to adjust the power level of the laser beam output from the laser unit 120. In addition, the laser annealing control unit 111 is configured to control the operation of the components of the laser microscope unit 130 for laser annealing operations. For example, the laser annealing control unit 111 is configured to control the operation of a laser beam shutter to control the duration of laser exposure when laser tuning a given Josephson junction. Further, in some embodiments, the laser annealing control unit 111 is configured to selective control the selection of target DOE component to position in the optical path to generate desired laser beam illumination patterns, the details of which will be explained in further detail below.

Further, in some embodiments, the imaging control unit 112 is configured to control the operation of the light source 131, the camera 132, and one or more of the optical components 136 (e.g., tube lens) that make up the image path of the laser microscope unit 130. For example, the imaging control unit 112 can generate camera control signals to cause the camera 132 to capture images within the FOV of the laser microscope unit 130 and send images to the imaging control unit 112. The imaging control unit 112 can be configured to preprocess the image data into a suitable format for processing by the data processing system 114 to perform computer vision operations such as automated pattern recognition functions to perform laser alignment and electrical probe alignment operations as discussed herein.

Moreover, in some embodiments, the prober control unit 113 is configured to control operations of the prober unit 140. For example, the prober control unit 113 comprises hardware for generating test voltages that are applied to the electrical probes for performing junction resistance measurements, e.g., for a 4-wire (Kelvin) resistance measurement, the prober control unit 113 may comprise current and voltage measurement circuitry, which is coupled to the electrical probes 144, and configured to measure current that flows through a Josephson junction as a result of applying a test voltage to the electrical probes, as well as measure a voltage across the Josephson junction. The measured currents and voltages can be digitized and sent to the data processing system 114 for computing junction resistances. In addition, the prober control unit 113 comprises control elements to precisely control movement and positioning of the X-Y-Z stage 142.

In some embodiments, the data processing system 114 executes a calibration process by performing laser annealing operations on Josephson junctions of representative hardware, using different combinations of laser anneal power and anneal time, to generate tuning calibration data (stored in the database of tuning calibration data 115). The tuning calibration data can be obtained by performing a calibration process on representative hardware which, in some embodiments, can be dummy Josephson junctions that reside on the same quantum chip to be tuned, and in other embodiments, can be Josephson junctions of qubits that are formed on a sister chiplet from the same fabrication process. The tuning calibration data is analyzed using statistical methods to fit the tuning calibration data to tuning curves, wherein the tuning curves are utilized to determine tuning rates and maximum tuning ranges for Josephson junctions under different laser anneal powers and anneal times. The tuning curves are utilized by the data processing system 114 to select a target combination of anneal power and annal time, as desired, for a target tuning rate and maximum tuning range for laser annealing Josephson junctions of the given quantum chip, post fabrication. In some embodiments, the tuning curves are used to predict an initial laser anneal operation (initial shot) for tuning a given Josephson junction to a certain target (e.g., 50% to target) on a first shot. The calibration process ensures a smooth and rapid approach to a target tuning for a given Josephson junction, while mitigating risk of both undershooting and overshooting the tuning.

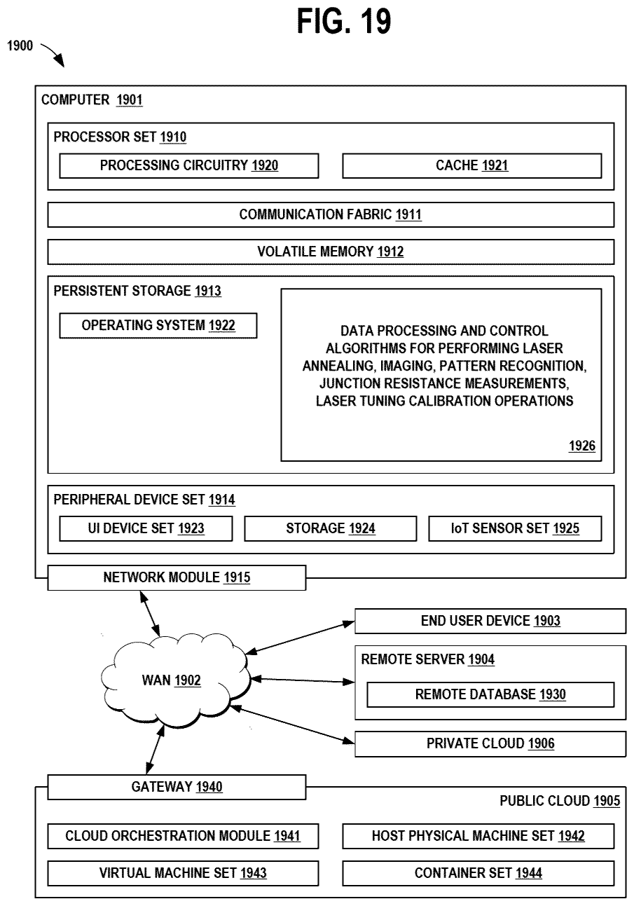

In some exemplary embodiments, the control system 110 for the laser annealing system 100 may be implemented using any suitable computing system architecture which is configured to implement methods to support the automated control processes as described herein by executing computer readable program instructions that are embodied on a computer program product which includes a computer readable storage medium (or media) having such computer readable program instructions thereon for causing a processor to perform control methods as discussed herein. An exemplary architecture of a computing environment for implementing a control system that is configured to control the exemplary laser annealing apparatus for tuning Josephson junctions as disclosed herein, will be discussed in further detail below in conjunction with FIG. 19.

It is to be noted that in the exemplary laser annealing system 100 of FIG. 1, the laser unit 120 and the laser microscope unit 130 collectively comprise an optical apparatus, and the prober unit 140 comprises an electrical characterization apparatus. The optical apparatus and the electrical characterization apparatus comprise an integrated configuration of a laser annealing apparatus that is configured to perform various operations, in-situ, to facilitate laser tuning of junction resistances of superconducting tunnel junction devices on a quantum chip (e.g., Josephson junctions), wherein such operations include, for example, laser annealing operations for laser tuning junction resistances of superconducting tunnel junction devices on a quantum chip, and in-situ resistance measurements to measure the junction resistances of the superconducting tunnel junction devices at any time before, during, and/or after the laser annealing operations, as needed, to determine or otherwise track the progression of the junction resistance shifts of the superconducting tunnel junction devices.

In some embodiments, the electrical characterization apparatus is configured to perform direct current (DC) resistance measurement operations to measure the junction resistances of the superconducting tunnel junction devices. In some embodiments, the electrical characterization apparatus is configured to perform alternating current (AC) resistance measurement operations to measure the junction resistances of the superconducting tunnel junction devices. In some embodiments, the resistance measurements are performed using 4-wire (Kelvin) resistance measurements for more precise measurements of junction resistances. In some embodiments, the electrical characterization apparatus comprises a wafer-scale prober apparatus (e.g., 200 millimeter (mm) or 300 mm wafer-scale prober apparatus) configured to perform the integrated electrical characterization techniques and discussed herein. The wafer prober comprises at least one of an automated and semi-automated wafer probing system.

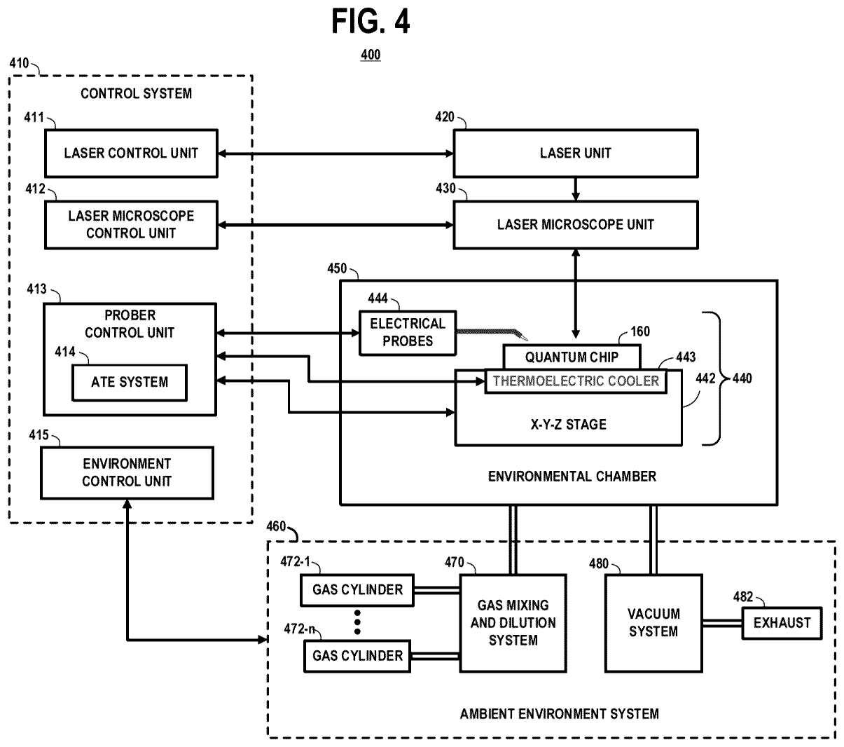

Furthermore, in some embodiments, as noted above, the electrical characterization apparatus (e.g., prober unit 140) comprises an environmental chamber (e.g., chamber 150, FIG. 1) that is configured to control an ambient environment of the quantum chip when performing the laser annealing operations. For example, the environmental chamber is configured to control the ambient environment by at least one of (i) controlling a composition of one or more gases within the environmental chamber, and (ii) generating a vacuum within the environmental chamber, as desired, when performing, e.g., laser annealing operations. Exemplary techniques for ambient environment control will be discussed in further detail below in conjunction with FIG. 4.

Moreover, in some embodiments, the electrical characterization apparatus (e.g., prober unit 14) comprises a thermal control system that is configured to at least one of (i) heat a quantum chip to perform a bulk thermal anneal operation for shifting the junction resistances of superconducting tunnel junction devices of the quantum chip, and (ii) cool the quantum chip to perform the in-situ resistance measurements.

It is to be noted that FIG. 1 illustrates an exemplary laser annealing apparatus in which the optical apparatus is implemented, in part, using a modular optical scope unit (e.g., the laser microscope unit 130), which comprises an optically integrated configuration of an imaging unit, optical components, a laser beam shaping device, and a laser beam focusing element. In particular, the laser microscope unit 130 comprises a modular optical scope unit with integrated components that are configured to generate, align, and project a desired laser beam pattern at the surface of the quantum chip to perform laser anneal operations. The laser microscope unit 130 is “modular” in that it provides an optical scope unit which comprises a packaged functional assembly of components to perform various functions (e.g., imaging, laser beam pattern generation and delivery, etc.), and which provides portability for use with suitable configurations of the laser unit 120 and the prober unit 140. The modular laser microscope unit 130 comprises a compact and portable optical scope assembly which can be mounted on a desired prober unit, and coupled to any suitable laser unit via a single mode optical fiber 126 to receive laser beam energy from a separate laser unit. In this regard, the modular laser microscope unit 130 does not include the actual laser source and, thus, can be made more compact and portable.

In this regard, on a fundamental level, the laser microscope unit 130 comprises a optical microscope device which comprises an optically integrated configuration of components for performing functions such as, e.g., imaging a target device within a field of view of the optical microscope device, laser annealing the target device by generating a laser beam spot pattern from a laser beam received on an optical fiber from a remote laser source, and controlling a duration of exposure of the laser beam spot pattern for laser annealing the target device. The optical microscope device comprises a modular device which is configured for mounting to an electrical characterization system to enable in-situ electrical characterization of the target device in conjunction with laser annealing, wherein in some embodiments, the electrical characterization system comprises a wafer-scale prober unit.

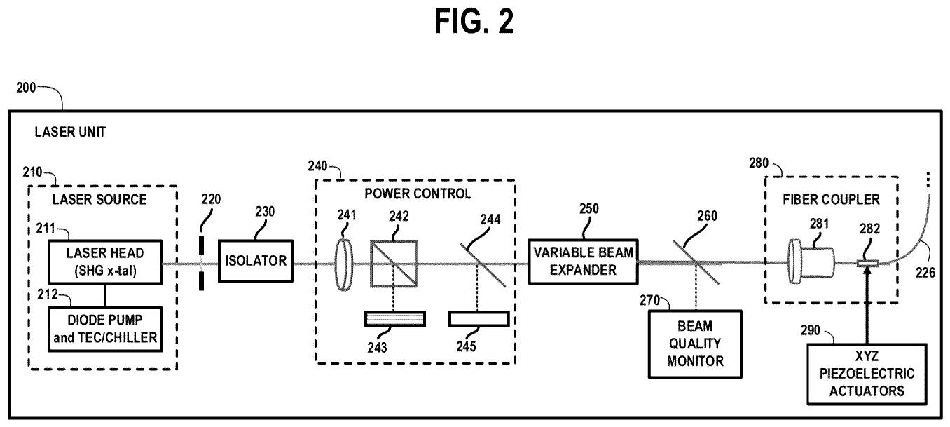

FIG. 2 schematically illustrates a laser unit according to an exemplary embodiment of the disclosure. More specifically, FIG. 2 schematically illustrates a laser unit 200 which comprises a laser source 210, an electronic shutter 220, an isolator 230, a power control block 240, a variable beam expander 250, a beam sampling device 260, a beam quality monitoring block 270, a fiber coupler 280, and XYZ piezoelectric actuators 290. The laser source 210 comprises a laser head 211, and a diode pump 212 that is configured to generate laser energy. The diode pump 212 is cooled using any suitable thermoelectric cooling (TEC) device. In some embodiments, the power control block 240 comprises a quarter-wave plate 241, a polarizing beam splitter (PBS) 242, a laser beam dump 243, a laser beam sampler device 244, and a photodiode 245. In some embodiments, the fiber coupler 280 comprises an objective lens 281, and a fiber optic ferrule 282 coupled to an input end of an optical fiber 226. In some embodiments, the laser unit 130 in the laser annealing system 100 of FIG. 1 can be implemented using the exemplary laser unit 200 of FIG. 2.

In some embodiments, the various components of the laser unit 200 operate in the following manner. The laser source 210 comprises a diode-pumped solid-state laser that is configured to generate, e.g., 532 nm second-harmonic generation laser beam which is utilized for laser annealing superconducting quantum devices. The electronic shutter 220 is operated to control the output (allow or block) of the laser beam from the laser unit 200. The isolator 230 is configured to provide polarization cleanup and optical isolation to mitigate unwanted feedback to the laser head 211 of the laser source 210.

The power control block 240 is configured monitor and control a power level of the laser beam that is output from the laser source 210. For example, the power control block 240 actively calibrates the laser beam power via the combination of the quarter-wave plate 241 and the polarizing beam splitter 242. For example, in some embodiments, the quarter-wave plate 241 is configured to shift a polarization direction of the laser beam output from the isolator 230, and comprises an adjustable rotation that can be electronically-controlled via a laser unit control module (e.g., laser annealing control unit 111, FIG. 1) to adjust a total attenuation by rotating the polarization incident on the polarizing beam splitter to the desired power level. In some embodiments, the polarizing beam splitter 242 comprises an optical filter that allows a specific polarization of light waves associated with the laser beam to pass through the optical filter and blocks light waves of other polarizations, to thereby generate a laser beam with well-defined polarized light. The laser beam dump 243 is configured to provide a termination for laser energy that is directed to the laser beam dump 243 from the polarizing beam splitter 242. The laser beam sampler device 244 is disposed in the laser beam path and configured to direct a portion of the laser beam energy to the silicon photodiode 245 to monitor the laser power level to set the appropriate laser power level for a laser anneal operation.

The variable beam expander 250 is configured to adjust a diameter of the laser beam that is input to the fiber coupler 280 to ensure that the optical fiber 226 is positioned at a beam focal point to optimize the optical coupling of the laser beam to the input of the optical fiber 226 by operation of the fiber coupler 280. In particular, the objective lens 281 is configured to focus the laser beam to a focal point for coupling the laser beam into the input end of the optical fiber 226. The fiber optic ferrule 282 is mounted to movable component that is controlled the XYZ piezoelectric actuators 290 to properly align (X-Y-Z alignment) the input end of the optical fiber 226 to the focal point of the objective lens 281 to thereby maximize the optical coupling of the laser beam into the input end of the optical fiber 226 for transmission to a laser microscope unit.

In some embodiments, the laser beam quality monitoring block 270 comprises an M2 laser beam measurement system that is configured measure the quality of the laser beam with respect to an M2 parameter which corresponds to a beam propagation ratio or beam quality factor, which represents a degree of variation of the laser beam from an ideal Gaussian beam. The laser beam sampler device 260 is disposed in the laser beam path and configured to direct a portion of the laser beam energy to the laser beam quality monitoring block 270 to measure and monitor the quality of laser beam.

FIG. 3A schematically illustrates a laser annealing apparatus comprising a modular laser microscope unit, according to an exemplary embodiment of the disclosure. In particular, FIG. 3A schematically illustrates a laser annealing apparatus comprising the laser unit 200 and optical fiber 226 (of FIG. 2), and a modular laser microscope unit 300. The laser unit 200 generates a laser beam which is transmitted to the modular laser microscope unit 300 via the optical fiber 226 which optically couples the laser unit 200 to the modular laser microscope unit 300. In some embodiments, the modular laser microscope unit 300 schematically illustrates an exemplary architecture for implementing the laser microscope unit 130 of the laser annealing apparatus system 100 of FIG. 1. In some embodiments, as noted above, the modular laser microscope unit 300 comprises an integrated optical system with various optical components to enable laser annealing operations and to enable optical visualization and characterization operations to precisely control and visualize laser illumination geometry and alignment for laser annealing operations.

In particular, the modular laser microscope unit 300 comprise various components that are disposed in optical paths to enable optical visualization and characterization operations, wherein such components include, e.g., a light source 301, a camera 302, a lens 303, a tube lens 304, a mirror 305, a beam splitter 306, a notch filter 307, a polarizing beam splitter 308 (with X-Y-Z piezoelectric actuator control), and an objective lens 309. The light source 301 and the camera 302 are configured for illuminating and viewing target features (e.g., qubits and corresponding Josephson junctions) on the surface of the quantum chip 160 within a given field of view (FOV) of the laser microscope unit 300. As noted above, the light source 301 comprises any suitable light generating device including one or more LED element with desired photonic wavelengths, a monochromatic light source, etc. The camera 320 may comprise a CCD image sensor, or an IR CMOS image sensor, etc.

The light source 301, the lens 303, the mirror 305, and the beam splitter 306, are configured to implement Kohler illumination in the optical viewing path to create uniform illumination of the target features in the FOV of the module laser microscope unit 300 and to ensure that an image of the light source 301 is not visible in the resulting images captured by the camera 302. In a light source path, the lens 303 is configured to “parallelize” the light emitted from the light source 301 to form an illumination beam 310. The illumination beam 310 is directed along an optical path by the mirror 305 to the beam splitter 306, through the notch filter 307, the polarizing beam splitter 308, and focused by the objective lens 309 to illuminate the portion of the quantum chip 260 within the FOV of the objective lens 309. The tube lens 304 comprises a multi-element optical component that is configured to focus parallel light coming through the objective lens 309 onto the image plane of a focal plane array of the camera 302. The notch filter 307 is configured to attenuate the light intensity at or near the wavelength (e.g., 532 nm) of the laser beam illumination using, e.g., engineered dielectric coatings or otherwise. In an exemplary embodiment, the notch filter 307 is selected to filter light at and near 532 nm, to prevent scattered and reflected light from the sample from saturating the camera 302, and enabling simultaneous laser annealing and optical imaging.

Furthermore, the modular laser microscope unit 300 comprise various components that are disposed in a laser beam path to perform various operations to enable laser annealing. For example, in the laser beam path, the modular laser microscope unit 300 comprises an optical fiber output interface element 311 (e.g., fiber optic ferrule), a fiber collimator lens 312, a switchable attenuator device 320, a variable beam expander 330, a clean-up polarizer 331, a power monitor 340 (which comprises a beam sampler 341 and photodiode 342), an electronic shutter 350, a spiral phase plate device 360, a mirror 370, and a switchable DOE device 380. In addition, the laser beam path comprises the polarizing beam splitter 308, and the objective lens 309.

In the laser beam path, the optical fiber output interface element 311 is aligned to the fiber collimator 312. The fiber collimator 312 is configured to collimate the laser light emitted from the end of the optical fiber 226 to generate a collimated laser beam 313. The switchable attenuator device 320 comprises a plurality of attenuation elements which can be selectively placed in the laser beam path of the collimated laser beam 313 to achieve a desired attenuation of the laser beam power (e.g., discrete attenuation levels in a range of 0% attenuation to 90% attenuation). As explained in further detail below, the switchable attenuator device 320 enables rapid control of laser annealing power for different thermal annealing profiles and operating conditions. The variable beam expander 330 is configured to controllably adjust (e.g., increase or decrease) the diameter of the collimated laser beam 313. The variable beam expander 330 is utilized to control a laser beam spot size for various laser beam illumination patterns which comprise one or more laser beam spots.

The clean-up polarizer 331 is configured to remove stray polarization modes (e.g. propagating in cladding modes) in advance of laser power measurements enabled by the power monitor 340, to thereby significantly increase the accuracy of laser power measurement. The power monitor 340 operates by utilizing the beam sampler 341 to direct some laser energy to the photodiode 342, and the photodiode generates an electrical signal that is measured (via a laser microscope control module) to determine the laser power level. The electronic shutter 350 is operated (via the laser microscope control module) for precise control of laser beam exposure for laser annealing a given quantum device (e.g., Josephson junction). In other words, the electronic shutter 350 enables precise control of an annal time for performing a given laser anneal operation. In some embodiments, the electronic shutter 350 may be used in conjunction with electronic shutter 220 of the laser unit 200, to minimize the impact of any vibrations induced from the shutter motion on the optical illumination. For example, the shutter 220 of the laser unit 200 may initially be closed while the shutter 350 is initially open, immediately prior to an anneal operation. When the anneal operation is to be commenced, the shutter 220 may open, and the laser spot pattern is exposed upon the Josephson junction (or junctions). By first opening the shutter 220, any vibrations incurred will be isolated to the laser unit 200 and will not impact the stability of the beam exiting the objective lens 309 on the modular laser microscope unit 300. Once the anneal operation is complete (i.e., some desired annealing time has elapsed), the anneal operation may be stopped by closing the shutter 350 on the laser microscope unit 300. Here, with the shutter close operation, any mechanical vibrations caused by the shutter 350 operation no longer impact the anneal operation, as the illumination has been blocked by shutter 350. Thus, by utilizing the two shutters 220 and 350 in the correct order, it is possible to eliminate the impact of mechanical vibrations on the optical beam stability.

The spiral (vortex) phase plate device 360 is configured to convert a laser beam spot (e.g., Gaussian laser spot) into laser beam with a vortex shape (e.g., annulus) which comprises a donut shape. As explained in further detail below, the spiral (vortex) phase plate device 360 is utilized in instances where a laser beam illumination pattern having one or more annulus-shaped laser beam spots is desired for laser annealing a given superconducting quantum device. On the other hand, the spiral (vortex) phase plate device 360 is not utilized in instances where a laser beam illumination pattern having one or more Gaussian-shaped laser spots is desired for laser annealing a given superconducting quantum device. In some embodiments, the spiral (vortex) phase plate device 360 is configured to adjust the shape of the annulus laser spot.

The mirror 370 is configured to direct a laser beam along an optical path the switchable DOE device 380. The switchable DOE device 380 comprises a plurality of laser beam shaping diffractive optical elements which can be selected to generate various types of laser beam illumination patterns (multi-spot patterns) having two or more Gaussian-shaped laser beam spots or two or more annulus-shaped laser beam spots, the details of which will be explained below. The switchable DOE device 380 comprises a variety of DOE components disposed on a rotatory stage, or a linear stage, which can be operated to place a given DOE element in the path of the laser beam to generate a target multi-spot laser beam illumination pattern to provide a desired thermal profile for laser annealing a given superconducting quantum device.

In some embodiments, the polarizing beam splitter 308 is mounted on an automated piezoelectric actuator stage to provide rapid precision alignment of a laser beam illumination pattern to a center of the FOV (field of view) of the objective lens 309. In some embodiments, the piezoelectric actuator stage comprises X-Y-Z actuators to fine tune the alignment between a laser beam illumination pattern and target superconducting quantum device in the FOV of the objective lens 309 in conjunction with an image pattern recognition process performed via pattern recognition of the target superconducting quantum device. In some embodiments, the pattern recognition process may be performed by comparing the sample image with a template image using a cross-correlation to determine the specific type of quantum device being annealed. However, in general, any other method which quantifies the similarity of a target image on the FOV to a template image, with the purpose of finding the best possible match amongst a series of template images, may be used.

FIG. 3B is a perspective view of a modular optical scope unit, according to an exemplary embodiment of the disclosure. In particular, FIG. 3B illustrates an exemplary modular optical scope unit 300-1, which is based on the exemplary integrated optical assembly architecture as schematically illustrated in FIG. 3A. The exemplary modular optical scope unit 300-1 shown in FIG. 3B comprises a portable, compact optical system that can be readily mounted on any suitable prober unit (e.g., wafer-level prober system) to integrate the optical and electrical characterization functionality of laser annealing apparatus to perform in-situ laser annealing and junction resistance measurement operations to facilitate laser tuning of superconducting tunnel junction devices on a quantum chip, e.g., perform a LASIQ process to tune transition frequencies of qubit devices in a given qubit lattice of the quantum chip 160. The various components described previously in FIG. 3A, where visible, are correspondingly numbered in the modular optical scope 300-1 in FIG. 3B.

FIG. 4 schematically illustrates a laser annealing system, according to another exemplary embodiment of the disclosure. In particular, FIG. 4 schematically illustrates a laser annealing system 400 which comprises a control system 410, a laser unit 420, a laser microscope unit 430, an electrical characterization system 440 (e.g., prober unit) disposed in an environmental microchamber 450, and an ambient environment system 460. The control system 410 comprises a laser control unit 411, a laser microscope control unit 412, a prober control unit 413 (which implements an automated test equipment (ATE) system 413), and an environment control unit 414.

The laser control unit 411 is configured to control the laser unit 420. The laser microscope control unit 412 is configured to control the laser microscope unit 430. The laser unit 420 can be implemented using one of the exemplary laser units 120 or 200 as discussed above in conjunction with FIGS. 1 and 2. The laser microscope unit 420 can be implemented using one of the exemplary modular, integrated laser microscope units 120 and 300 as discussed above in conjunction with FIGS. 1 and 3A and 3B.

The prober control unit 413 is configured to control the electrical characterization system 440 (e.g., prober unit). The electrical characterization system 440 (e.g., prober unit) comprises an X-Y-Z stage 442 having a wafer chuck which comprises a thermoelectric cooler 443, and electrical probes 444. The electrical characterization system is similar in configuration and operation of the prober unit 140 discussed above in conjunction with FIG. 1, except that the exemplary electrical characterization system 440 implements the thermoelectric cooler 443 to provide a thermal control system (e.g., temperature-controlled wafer chuck system, or other suitable types of heating/cooling systems) that is configured to (i) heat the quantum chip 160 to perform a bulk thermal anneal operation for shifting the junction resistances of the tunnel junction devices of the quantum chip 160, and (ii) cool the quantum chip 160 to perform the in-situ resistance measurements, as will be discussed in further detail below. In some embodiments, a temperature-controlled wafer chuck system can be temperature controlled in a range of −60° C. to 300° C. The ATE system 414 comprises a combination of hardware and software to control automated operations of the electrical characterization system 400 (e.g., automated movement of probes, generating test signals, processing resulting voltage/current signals generated as a result of resistance measurement probing operations, etc.)

The electrical characterization system 440 is housed or otherwise disposed within the environmental chamber 450 to control an ambient environment within the environmental chamber 450 by operation of the environment control unit 415 and the ambient environment system 460. The ambient environment system 460 comprises a gas mixing and dilution system 470, which comprises an environmental gas control system which is coupled to the environmental chamber 450 and which is configured to inject a mixture of one or more gases into the environmental chamber 450 to control the annealing environment. The gas mixing and dilution system 470 is connected to a plurality of gas cylinders 472-1, . . . , 472-n, which store different gases (e.g., nitrogen, dry air, etc.). The gas mixing and dilution system 470 operates under control of the environment control unit 430 to mix different gases at various concentrations and inject the mixed gases into the environmental chamber 450, as desired, to provide a given gas environment for laser annealing. In addition, the ambient environment system 460 comprises a vacuum system 480 coupled to the environmental chamber 450 to evacuate anneal gases from the chamber 450 or otherwise evacuate air from the environmental chamber 550 to perform laser annealing in a vacuum atmosphere. An exhaust system 482 is coupled to the vacuum system 480, wherein the exhaust system is configured to direct the evacuated gases for proper disposal.

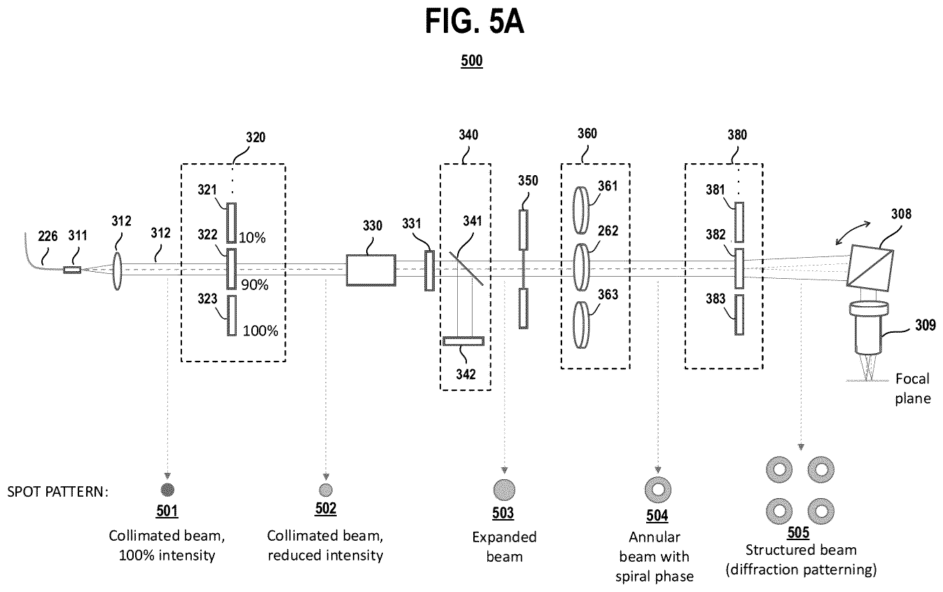

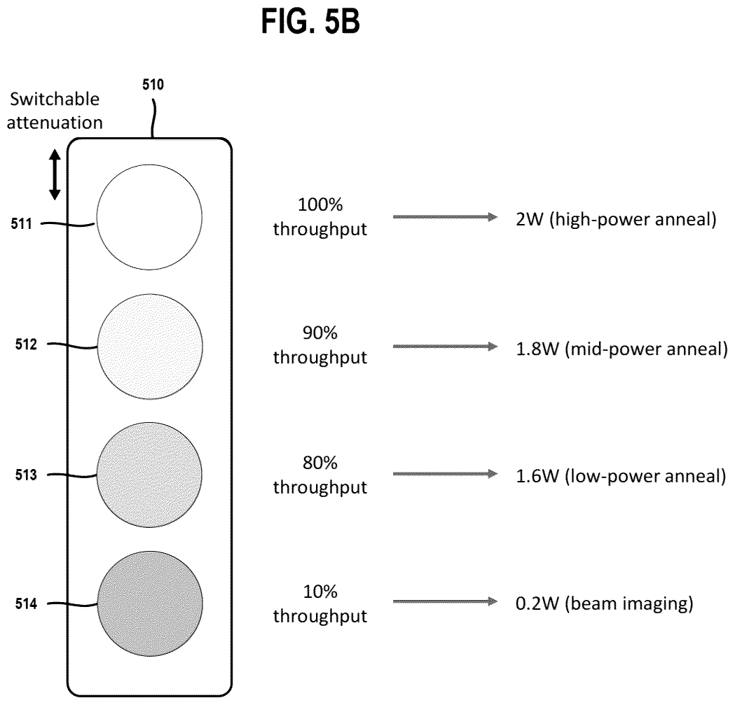

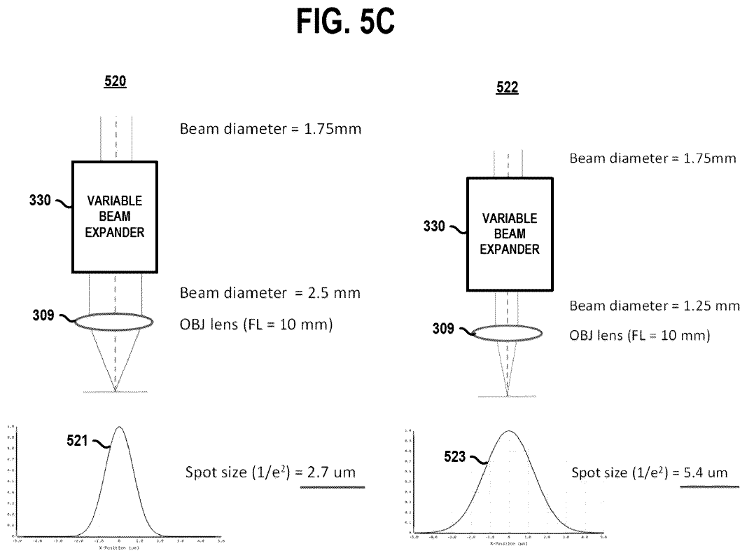

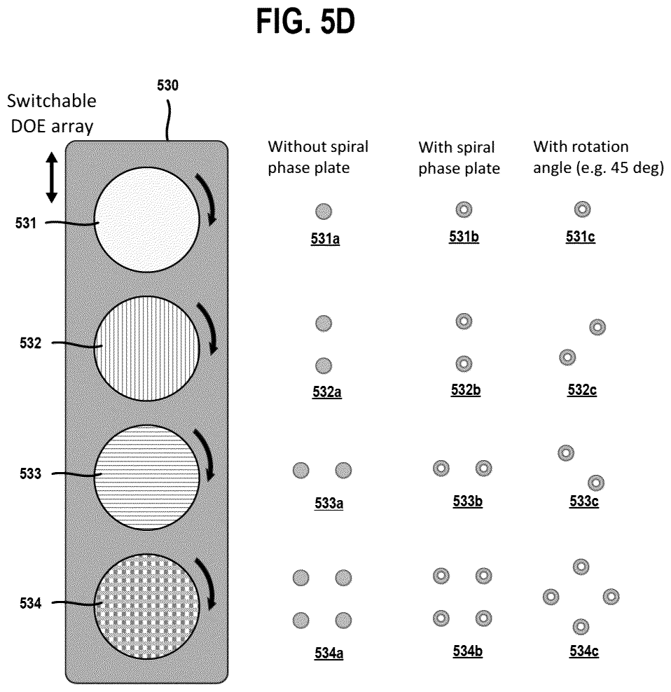

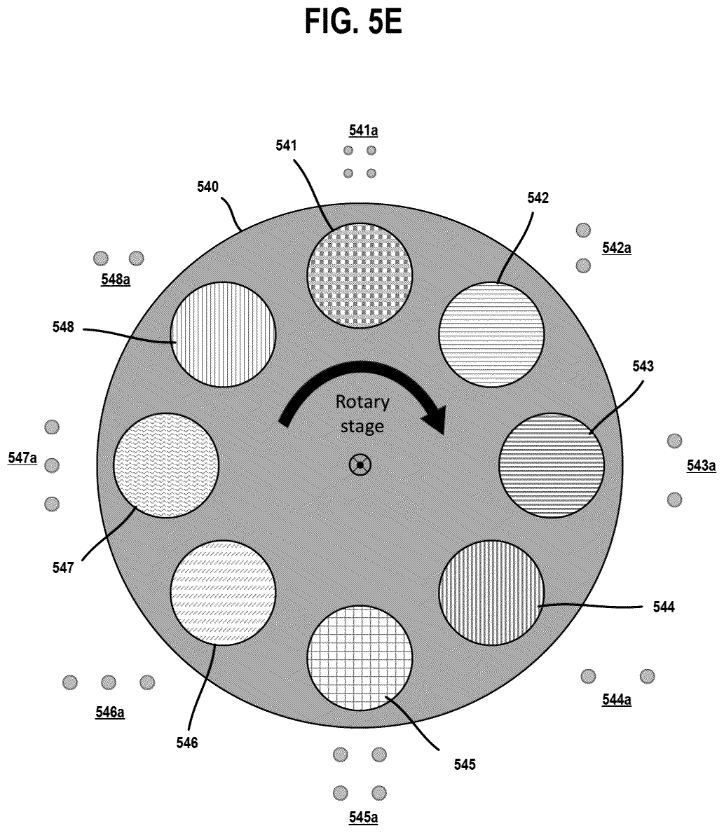

Various exemplary modes of operation of the exemplary laser microscope unit 300 of FIG. 3A will now be discussed in further detail in conjunction with FIGS. 5A, 5B, 5C, 5D, and 5E. For example, FIG. 5A schematically illustrates a method for generating a laser beam illumination pattern using, according to an exemplary embodiment of the disclosure. In particular, FIG. 5A schematically illustrates a method 500 for generating a multi-spot laser beam illumination pattern using the laser microscope unit 300 of FIG. 3A. FIG. 5A illustrates various operating modes of the various components, e.g., the fiber collimator lens 312, the switchable attenuator device 320, the variable beam expander 330, the spiral phase plate device 360, the switchable DOE device 380, and the XYZ piezo-controlled PBS 308, for generating a desired laser beam illumination pattern and focusing and aligning the laser beam illumination to a given superconducting quantum device.

As schematically illustrated in FIG. 5A, the fiber collimator lens 312 collimates laser light emitted from the end of the optical fiber 226 to generate a collimated laser beam 313 which provides an initial laser beam spot 501 having an initial diameter and full intensity (100%). The switchable attenuator device 320 comprises a plurality of attenuation elements 321, 322, and 323, which can be selectively placed in the laser beam path to achieve a desired attenuation of the collimated laser beam (e.g., achieve a desired power attenuation level or, alternatively, a desired power throughput level). FIG. 5A illustrates an exemplary mode of operation in which the switchable attenuator device 320 is operatively controlled to select and place the attenuation element 322 in the laser beam path to achieve a 90% power throughput level (or 10% attenuation level) and, thereby, generate a collimated laser beam which provides a laser beam spot 502 having the same initial diameter but with 90% of the initial full intensity.

Next, FIG. 5A illustrates an exemplary mode of operation in which the variable beam expander 330 is configured to expand the size of the laser beam spot 502 to generate an expanded laser beam spot 503 having a spot diameter which is greater than the spot diameter of the laser beam spot 502. It is to be noted that is some embodiments, the laser beam spots 501, 502, and 503 comprise Gaussian beams, which have high monochromaticity, and an intensity profile (in the transverse plane) which corresponds to a Gaussian function.

The spiral phase plate device 360 comprises a plurality of spiral phase plates 361, 362, and 363, which can be selectively placed in the laser beam path to convert the expanded laser beam spot 503 (Gaussian laser spot) to an annular laser beam spot 504 with a given spiral phase that determines the geometry of the annular laser beam spot 504. Each spiral phase plate 361, 362, and 363 is configured to form an annular laser beam profile with a spiral phase distribution, but where the spiral phase plates 361, 362, and 363 are configured to generate different annular laser beam profiles with variable annular and beam hole diameters. FIG. 5A illustrates an exemplary mode of operation in which the spiral phase plate device 360 is operatively controlled to select and place the spiral phase plate 362 in the laser beam path to achieve the exemplary annular laser beam spot 504.

Next, the switchable DOE device 380 comprises a plurality of beam shaping diffractive optical elements 381, 382, and 383, which can be selected to convert the single laser beam spot 504 into a multi-spot illumination pattern with a given spot geometry. For example, FIG. 5A illustrates an exemplary mode of operation in which the switchable DOE device 380 is operatively controlled to select and place the diffractive optical element 382 in the laser beam path to generate a quad-spot pattern 505 comprising four (4) annular laser beam spots based on the single annular laser beam spot 504. As noted above, the switchable DOE device 380 comprises an array of laser beam shaping diffractive optical elements which can be selected to generate various types of laser beam illumination patterns (multi-spot patterns) having two or more Gaussian-shaped laser beam spots or two or more annulus-shaped laser beam spots, the details of which will be explained in below. Finally, FIG. 5A schematically illustrates an exemplary mode of operation in which the polarizing beam splitter 308, which is mounted on an automated piezoelectric actuator stage, is positive to provide a precision alignment of a laser beam illumination pattern 505 to a center of the FOV of the objective lens 309.

FIG. 5B schematically illustrates a method for controlling laser power in a laser beam path of a laser microscope unit, according to an exemplary embodiment of the disclosure. More specifically, FIG. 5B schematically illustrates a switchable attenuator device 510 comprising a linear array of attenuation elements 511, 512, 513, and 514, according to an exemplary embodiment of the disclosure. The switchable attenuator device 510 can be used to implement the switchable attenuator device 320 (FIGS. 3A and 5A) wherein the switchable attenuator device 510 is configured to be automatically moved back and forth in a linear direction (as indicated by the double ended arrow) to selectively place one of the attenuation elements 511, 512, 513, and 514 in the laser beam path to achieve a desired level of power throughput.

The optical attenuator elements 511, 512, 513, and 514 are formed with different materials that have variable optical densities at the given operating laser light wavelength. For example, in some embodiments, the attenuation element 511 is configured to provide 100% throughput of laser power (or no laser power attenuation) under certain operation conditions (e.g., when performing a high-power laser anneal operation). The attenuation element 512 is configured to provide 90% throughput of laser power (or 10% laser power attenuation) under certain operation conditions (e.g., when performing a mid-power laser anneal operation). The attenuation element 513 is configured to provide 80% throughput of laser power (or 20% laser power attenuation) under certain operation conditions (e.g., when performing a low-power laser anneal operation). The attenuation element 514 is configured to provide 120% throughput of laser power (or 90% laser power attenuation) under certain operation conditions such as, e.g., when utilizing computer vision for imaging a given laser beam illumination pattern for purposes of aligning the laser beam illumination pattern to the center of the FOV of the objective lens or otherwise aligning the laser beam illumination pattern to a given superconducting quantum device (e.g., one or more Josephson junctions of a qubit).

FIG. 5C schematically illustrates a method for adjusting a laser beam spot size using a variable beam expander of a laser microscope unit, according to an exemplary embodiment of the disclosure. For example, FIG. 5C schematically illustrates a method 520 for adjusting a laser beam spot size in which the variable beam expander 330 is configured to expand a diameter of an input collimated laser beam, which has a beam diameter of 1.75 mm, to a collimated laser beam having an expanded beam diameter of 2.5 mm. Assuming the objective lens 309 has a focal length (FL) of 10 mm, FIG. 5C graphically illustrates a transverse intensity profile 521 of an exemplary laser beam spot having a Gaussian beam profile and spot size of 2.7 microns. The graph illustrates the transverse intensity profile 521 (e.g., W/m²) as a function of a radial position from a laser beam axis (optical centerline of laser beam). In addition, FIG. 5C schematically illustrates a method 522 for adjusting a laser beam spot size in which the variable beam expander 330 is configured to reduce a diameter of an input collimated laser beam, which has a beam diameter of 1.75 mm, to a collimated laser beam having a reduced beam diameter of 1.25 mm. Assuming the objective lens 309 has a focal length (FL) of 10 mm, FIG. 5C graphically illustrates a transverse intensity profile 523 of an exemplary laser beam spot having a Gaussian beam profile and spot size of 5.4 microns.

Next, FIG. 5D schematically illustrates a method for generating different laser beam illumination patterns using a laser microscope unit, according to an exemplary embodiment of the disclosure. More specifically, FIG. 5D schematically illustrates a switchable DOE device 530 comprising a linear array of laser beam shaping diffractive optical elements 531, 532, 533, and 534 which can be selected to generate various types of laser beam illumination patterns (multi-spot patterns) having one or more Gaussian-shaped laser beam spots. The switchable DOE device 530 can be used to implement the switchable DOE device 320 (FIGS. 3A and 5A) wherein the switchable DOE device 530 configured to be moved back and forth in a linear direction (as indicted by the double ended arrow) to automatically place one of the diffractive optical elements 531, 532, 533, and 534 in the laser beam path to achieve a desired laser beam spot pattern. The diffractive optical elements 531, 532, 533, and 534 are configured to have variable grating structures to generate different spot patterns. The laser beam spot pattern can include a single laser beam spot, a plurality of laser beam spots arranged in a square or rectangular pattern, or a linear pattern, or any combination thereof. The laser beam spots of a given illumination pattern can include a Gaussian profile, or an annular profile with a given spiral phase distribution.

For example, as schematically shown in FIG. 5D, the optical element 531 comprises a “null” default element (e.g., a transparent window, or an empty slot) that is configured to allow the beam to pass through with its beam profile unaffected, thus generating a single laser beam spot 531a. The diffractive optical element 532 comprises a grating structure that is configured to generate a vertical linear pattern of two laser beam spots 532a. The diffractive optical element 533 comprises a grating structure that is configured to generate a horizontal linear pattern of two laser beam spots 533a. The diffractive optical element 534 comprises a grating structure that is configured to generate a square pattern of four laser beam spots 533a (quad-spot laser beam illumination pattern).

In addition, FIG. 5D further illustrates laser beam illumination patterns 531b, 532b, 533b, and 534b having laser beam spots with annular profiles, which are generated by the respective diffractive optical elements 531, 532, 533, and 534 when a given spiral phase plate is utilized to generate a laser beam spot with an annular profile, and the annular laser beam spot is passed through the grating structures of the respective diffractive optical elements 531, 532, 533, and 534. In addition, FIG. 5D further illustrates laser beam illumination patterns 531c, 532c, 533c, and 534c which are generated by rotating the respective diffractive optical elements 531, 532, 533, and 534 by 45 degrees (in a direction as indicated by the single-ended curves arrows).

Next, FIG. 5E schematically illustrates a method for generating different laser beam illumination patterns using a laser microscope unit, according to an exemplary embodiment of the disclosure. More specifically, FIG. 5E schematically illustrates a switchable DOE device 540 comprising a circular array of laser beam shaping diffractive optical elements 541, 542, 543, 544, 545, 546, 547, and 548 that are disposed on a rotary stage, which can be selected to generate various types of laser beam illumination patterns (multi-spot patterns) having one or more Gaussian-shaped laser beam spots. The switchable DOE device 540 can be used to implement the switchable DOE device 320 (FIGS. 3A and 5A) wherein the switchable DOE device 540 is configured to rotate (as indicted by a single-ended curved arrow to automatically place one of the diffractive optical elements 541, 542, 543, 544, 545, 546, 547, and 548 in the laser beam path to achieve a desired laser beam spot pattern. The diffractive optical elements 541, 542, 543, 544, 545, 546, 547, and 548 are configured to have variable grating structures to generate respective laser beam spot patterns 541a, 542a, 543a, 544a, 545a, 546a, 547a, and 548a.

The laser beam spot patterns 541a and 545a each comprise a square pattern of four laser beam spots, but with different spacings (spot separation) between the laser beam spots. In particular, the spot separation of the laser beam spot pattern 545a is greater than the spot separation of the laser beam spot pattern 541a. Next, the laser beam spot patterns 542a and 548a each comprise a linear array of two laser beam spots with the same spot separation, but with different orientations (e.g., the laser beam spot pattern 542a is vertically oriented, and the laser beam spot pattern 548a is horizontally oriented). The laser beam spot patterns 543a and 544a each comprise a linear array of two laser beam spots with the same spot separation, but with different orientations (e.g., the laser beam spot pattern 543a is vertically oriented, and the laser beam spot pattern 544a is horizontally oriented). As schematically illustrated in FIG. 5E, the spot separation of the laser beam spot patterns 543a and 544a is greater than the spot separation of the laser beam spot patterns 542a and 548a. Next, the laser beam spot patterns 546a and 547a each comprise a linear array of three laser beam spots with the same spot separation, but with different orientations (e.g., the laser beam spot pattern 547a is vertically oriented, and the laser beam spot pattern 546a is horizontally oriented).

It is to be noted that while FIG. 5E schematically illustrates various laser beam illumination patterns having multiple laser spots with Gaussian profiles, the diffractive optical elements 541, 542, 543, 544, 545, 546, 547, and 548 can generate the same laser beam spot patterns with annular-shaped laser beams spots by passing a single annular-shaped laser beam through the diffractive optical elements 541, 542, 543, 544, 545, 546, 547, and 548. In addition, as noted above, the diameters of the laser beam spots can be expanded/reduced as desired using the zoom beam expander in the laser beam path upstream of a spiral phase plate and diffractive optical element.

When performing laser annealing operations, a laser power of 1-2 watts may be used during junction annealing to achieve a desired resistance change. Ideally, the laser spots in a given multi-spot pattern should be tightly spaced (10-15 μm separation) for efficient junction heating. For a given diffractive optical elements, the spot separation decreases as a grating pitch of the diffractive optical element increases. Preferably, the input beam diameter should be >3× the grating pitch. Larger input beam diameters lead to smaller focused spot sizes. If the laser spot size is too small, substrate damage may occur. In this regard, for tightly spaced DOE spot patterns a spiral (Vortex) phase plate can be utilized to generate an annular laser beam spot with double the laser spot size, while lowering the peak irradiance of the focused laser beam spot by about ⅕ as compared to a Gaussian laser beam spot, which significantly reduces the possibility of substrate damage.

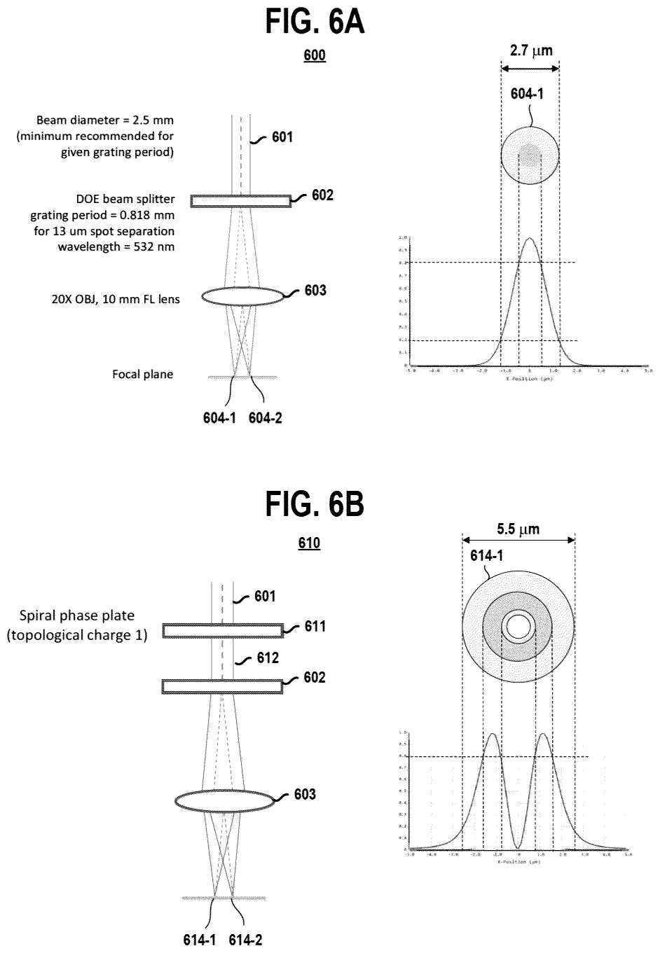

For example, FIG. 6A schematically illustrates a process 600 for generating a dual laser beam spot pattern having Gaussian laser beam spots, according to an exemplary embodiment of the disclosure. A collimated laser beam 601 having a beam diameter of 2.5 mm (and a laser wavelength of 532 nm) is passed through a diffractive optical element 602 having a grating period of 0.818 mm to generate two laser beams that are ultimately focused by an objective lens 603 at a focal plane to generate two laser beam spots 604-1 and 604-2 having a spot separation of 13 microns and a Gaussian profile. FIG. 6A further illustrates the laser beam spot 604-1 having a Gaussian profile and spot size of 2.7 microns.

Next, FIG. 6B schematically illustrates a process 610 for generating a dual laser beam spot pattern having annular laser beam spots, according to an exemplary embodiment of the disclosure. The process 610 of FIG. 6B is similar to the process 610 of FIG. 6A, except that the collimated laser beam 601 (having a beam diameter of 2.5 mm and a laser wavelength of 532 nm) is initially passed through a spiral phase plate 611 to convert the profile of the collimated laser beam 601 from a Gaussian profile to a laser beam 612 with an annular profile. The laser beam 612 with the annular profile is passed through the diffractive optical element 602 (having the grating period of 0.818 mm) to generate two laser beams that are ultimately focused by the objective lens 603 at a focal plane to generate two laser beam spots 614-1 and 614-2 having an annular profile. FIG. 6B further illustrates the laser beam spot 614-1 having an annular profile and spot size of 5.5 microns.

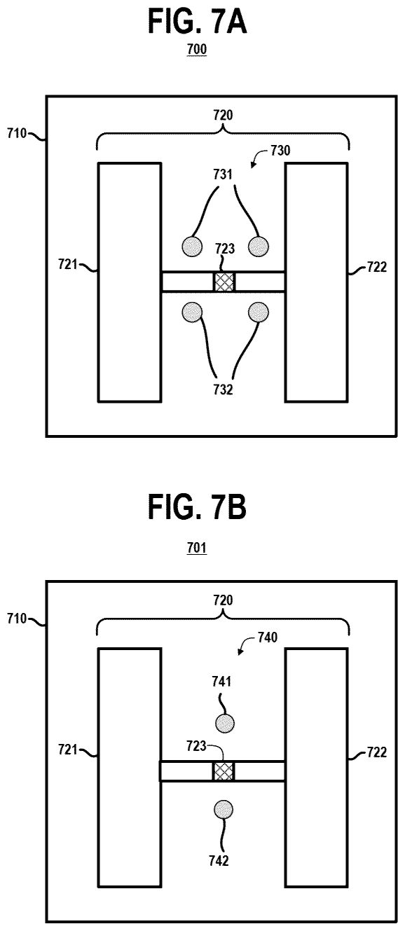

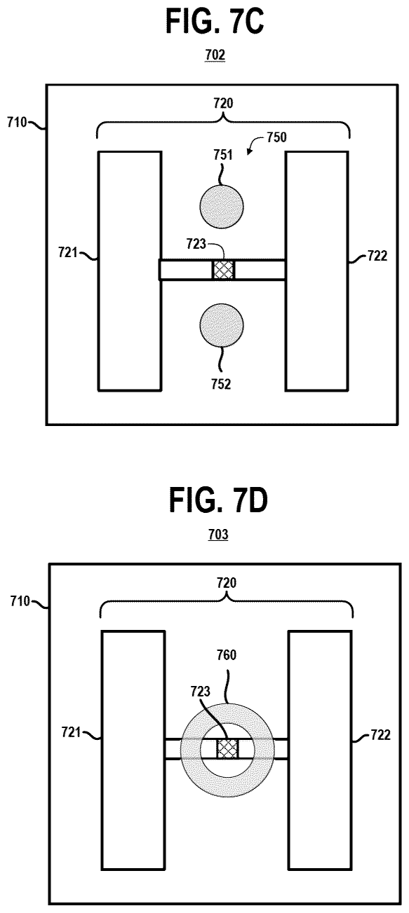

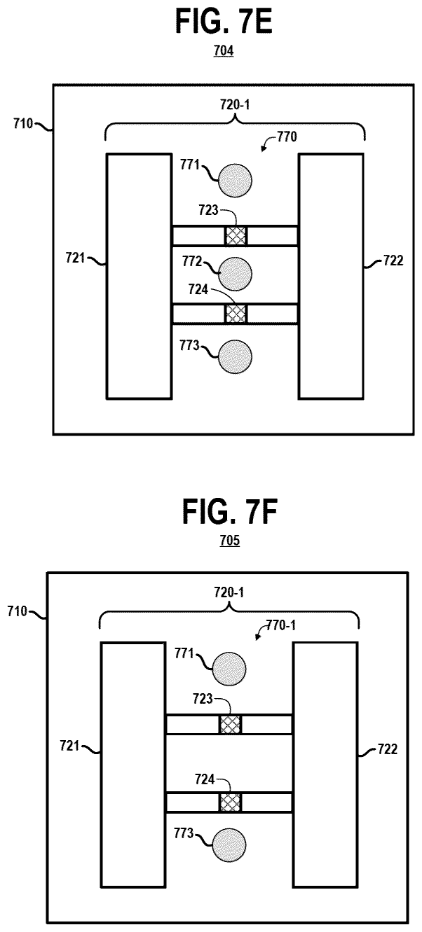

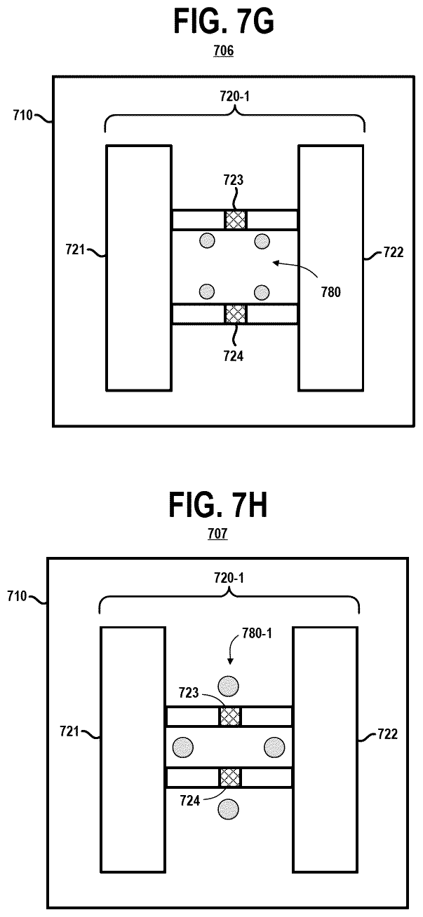

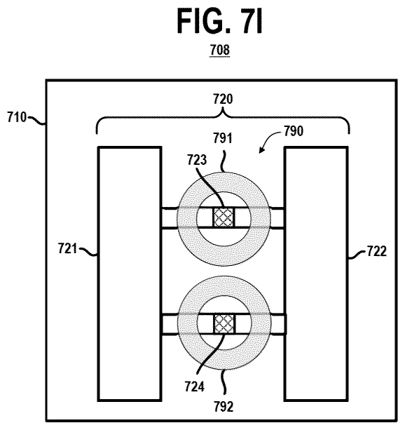

It is to be appreciated that different laser beam illumination patterns provide different thermal profiles for laser annealing. In particular, different laser beam illumination patterns can be used to provide different thermal profiles for laser annealing superconducting quantum devices (e.g., qubits) which have different geometries of Josephson junction. FIGS. 7A-7I schematically illustrate different types of laser illumination patterns that can be used to provide different thermal profiles for laser annealing and tuning quantum devices (e.g., quantum bits) that have different Josephson junction geometries, according to exemplary embodiments of the disclosure.

For example, FIG. 7A schematically illustrates a process 700 for laser annealing a quantum device using a laser beam illumination pattern, according to an exemplary embodiment of the disclosure. In particular, FIG. 7A illustrates an exemplary FOV 710, a superconducting qubit 720, and a quad-spot laser beam pattern 730. In some embodiments, the FOV 710 represents the area of the object that is imaged by a laser microscope unit (e.g., laser microscope unit 130 (FIG. 1) or laser microscope unit 300 (FIG. 3A)), wherein the size of the FOV 710 is generally determined by the magnification of the objective lens. In the exemplary architecture of the laser microscope unit, the FOV of the objective lens is applied to an image sensor (e.g., focal plane array) of the camera. Since the image sensor is rectangular in shape, the images captured by the laser microscope unit have a rectangular FOV, as shown in FIG. 7A, which does not capture the full circular FOV from the objective lens.

In FIG. 7A, the superconducting qubit 720 comprises a transmon qubit comprising a capacitor and Josephson junction connected in parallel. In particular, the superconducting qubit 720 comprises a first superconducting pad 721, a second superconducting pad 722, and a Josephson junction 723 coupled to, and disposed between, the first and second superconducting pads 721 and 722. The first and second superconducting pads 721 and 722 comprise electrodes of a coplanar parallel-plate capacitor structure of the superconducting qubit 720. The Josephson junction 723 functions as a non-linear inductor which, when shunted with the capacitor formed by the first and second superconducting pads 721 and 722, forms an anharmonic LC oscillator with individually addressable energy levels (e.g., two lowest energy level corresponding to the ground state |0) and the first excited state |1)) with a given transition frequency f₀₁.

FIG. 7A schematically illustrates an exemplary laser anneal process 700 for tuning the resistance of the Josephson junction 723 using a quad-spot laser beam pattern 730. The quad-spot laser beam pattern 730 comprises four (4) laser beam spots which correspond to, e.g., four laser beams that are generated by a diffractive optical element (a 2-by-2 diffractive beam splitter) and focused onto a surface (focal plane) of a quantum chip via the laser microscope unit. The quad-spot laser beam pattern 730 is aligned to the Josephson junction 723 such that two laser spots 731 are positioned on one side (e.g., above) of the Josephson junction 723, and two laser spots 732 are positioned on an opposite side (e.g., below) the Josephson junction 723. The quad-spot laser beam pattern 730 is configured to illuminate (and heat) regions of the upper surface of the quantum chip in proximity to the Josephson junction 723, but not directly illuminate the Josephson junction 723. The quad-spot laser beam pattern 730 is configured to uniformly heat the region surrounding the Josephson junction 723, without directly illuminating the Josephson junction 723 with a laser beam spot.

Next, FIG. 7B schematically illustrates a process 701 for laser annealing a quantum device using a laser beam illumination pattern, according to another exemplary embodiment of the disclosure. It is to be noted that FIG. 7B is similar to FIG. 7A except that FIG. 7B schematically illustrates an exemplary dual-spot laser beam pattern 740 which is aligned to the Josephson junction 723 such that a first laser beam spot 741 is positioned on one side (e.g., above) of the Josephson junction 723, and a second laser beam spot 742 is positioned on an opposite side (e.g., below) the Josephson junction 723. The dual-spot laser beam illumination pattern 740 is configured to illuminate (and heat) regions of the upper surface of the quantum chip in proximity to the Josephson junction 723, but not directly illuminate the Josephson junction 723.

Next, FIG. 7C schematically illustrates a process 702 for laser annealing a quantum device using a laser beam illumination pattern, according to another exemplary embodiment of the disclosure. It is to be noted that FIG. 7C is similar to FIG. 7B in that FIG. 7C schematically illustrates an exemplary dual-spot laser beam illumination pattern 750 which comprises a first laser beam spot 751 positioned on one side (e.g., above) of the Josephson junction 723, and a second laser beam spot 752 positioned on an opposite side (e.g., below) the Josephson junction 723. However, the first and second laser beam spots 751 and 752 of the dual-spot laser beam illumination pattern 750 are larger in diameter than the first and second laser beam spots 741 and 742 of the dual-spot laser beam pattern 740 of FIG. 7B. In this regard, the first and second laser beam spots 751 and 752 of the laser beam illumination pattern 750 are configured to illuminate (and heat) a larger area of the substrate surface on opposing sides of the Josephson junction 723.

Further, FIG. 7D schematically illustrates a process 703 for laser annealing a quantum device using a laser beam illumination pattern, according to another exemplary embodiment of the disclosure. FIG. 7D schematically illustrates an exemplary annular laser beam illumination pattern 760 which is configured to illuminate (heat) a ring-shaped area that surrounds the Josephson junction 523, but without directly illuminating the Josephson junction 723 with laser energy. The annular laser beam illumination pattern 760 achieves a significantly high temperature to anneal the Josephson junction 723 without directly heating the Josephson junction 723. The exemplary annular laser beam illumination pattern 760 with a low intensity center region can uniformly heat the substrate surrounding the Josephson junction 723 junction, without damaging the Josephson junction 723 junction. As noted above, the annular laser beam illumination pattern 760 may be achieved using a spiral phase plate with a selected topological charge to engineer the relative dimensions of the annulus.

It is to be noted that while FIGS. 7A, 7B, 7C and 7D schematically illustrate a superconducting qubit 720 comprising a single Josephson junction 723, other types of superconducting qubits or quantum devices can have two or more Josephson junctions, wherein the two or more Josephson junctions can be laser annealed concurrently using a suitable laser illumination pattern. For example, some quantum devices, such as tunable qubits or qubit couplers, comprise a SQUID, wherein the SQUID comprises a pair of Josephson junctions which are connected in parallel to form a superconducting loop (referred to as SQUID loop) through which an external magnetic flux ¢ can be threaded to tune the operations of the quantum devices. In this regard, the Josephson junctions of a SQUID can be laser annealed and tuned concurrently by utilizing a suitable laser illumination pattern that is configured to heat the substrate regions surrounding the two Josephson junctions of the SQUID.

For example, FIG. 7E schematically illustrates a process 704 for laser annealing a quantum device using a laser beam illumination pattern, according to another exemplary embodiment of the disclosure. In particular, FIG. 7E illustrates an exemplary flux-tunable superconducting qubit 720-1 which is similar to the superconducting qubit 720 of FIGS. 7A-7D, except that flux-tunable superconducting qubit 720-1 comprises two Josephson junctions 723 and 724 which collectively comprise a SQUID, and are connected in parallel between the first and second superconducting pads 721 and 722 to form a superconducting loop through which a magnetic flux is threaded to tune the operating frequency of the flux-tunable superconducting qubit 720-1. In addition, FIG. 7E schematically illustrates an exemplary three-spot laser beam illumination pattern 770 which is aligned to the two Josephson junctions 723 and 724 such that a first laser beam spot 771 is positioned on one side (e.g., above) of the Josephson junction 723, a second laser beam spot 772 positioned between the two Josephson junctions 723 and 724, and a third laser beam spot 773 is positioned on an opposite side (e.g., below) the Josephson junction 724. In this regard, the three-spot laser beam pattern 770 is implemented and configured to concurrently laser tune the two Josephson junctions 723 and 724 of the flux-tunable superconducting qubit 720-1.

Next, FIG. 7F schematically illustrates a process 705 for laser annealing a quantum device using a laser beam illumination pattern, according to another exemplary embodiment of the disclosure. FIG. 7F schematically illustrates an exemplary two-spot laser beam illumination pattern 770-1 which is similar to the laser beam illumination pattern 770 of FIG. 7E, except that the exemplary two-spot laser beam illumination pattern 770-1 does not include a laser beam spot positioned between the two Josephson junctions 723 and 724. Instead, the exemplary two-spot laser beam illumination pattern 770-1 comprise the two laser beam spots 771 and 773 which are aligned and positioned above and below the respective Josephson junctions 723 and 724.

FIG. 7G schematically illustrates a process for laser annealing a quantum device using a laser beam illumination pattern, according to another exemplary embodiment of the disclosure. In particular, FIG. 7G illustrates a process 706 for laser annealing the exemplary flux-tunable superconducting qubit 720-1 using a quad-spot laser beam pattern 780 in which a pattern of four laser beam spots is aligned and positioned between the two Josephson junctions 723 and 724. In this regard, the quad-spot laser beam pattern 780 is implemented and configured to concurrently laser tune the two Josephson junctions 723 and 724 of the flux-tunable superconducting qubit 720-1.

FIG. 7H schematically illustrates a process for laser annealing a quantum device using a laser beam illumination pattern, according to another exemplary embodiment of the disclosure. In particular, FIG. 7H illustrates a process 707 for laser annealing the exemplary flux-tunable superconducting qubit 720-1 using a quad-spot laser beam pattern 780-1 which is similar to the quad-spot laser beam pattern 780 of FIG. 7G, but rotated 45 degrees to achieve a different thermal profile for concurrently laser annealing the two Josephson junctions 723 and 724.

Next, FIG. 7I schematically illustrates a process for laser annealing a quantum device using a laser beam illumination pattern, according to another exemplary embodiment of the disclosure. In particular, FIG. 7I illustrates process 708 for laser annealing the exemplary flux-tunable superconducting qubit 720-1 using a dual-annular laser beam pattern 790 which comprises a first annular laser beam pattern 791 and a second annular laser beam pattern 792. As schematically shown in FIG. 7I, the dual-annular laser beam pattern 790 is aligned to the first and second Josephson junctions 723 and 724 such that the first annular laser beam pattern 791 is positioned to surround the first Josephson junction 723, and the second annular laser beam pattern 792 is positioned to surround the second Josephson junction 724. In this regard, the dual-annular laser beam pattern 790 can be implemented and configured to concurrently laser tune the first and second Josephson junctions 723 and 724 of the flux-tunable superconducting qubit 720-1.

It is to be appreciated that a wide variety of laser illumination patterns and geometries can be implemented for laser annealing and tuning Josephson junctions that occur in various geometries, e.g., single-junction or multi-junction configurations for a variety of quantum devices, e.g., fixed-frequency superconducting qubits, flux-tunable superconducting qubits, flux-tunable couplers that control interactions between quantum bits, etc. The exemplary laser beam illumination geometries shown in FIGS. 7A-7I are configured to provide different thermal profiles for laser annealing and tuning Josephson junction with different power levels depending on the illumination geometry. For example, comparing the exemplary illumination geometries of FIGS. 7A and 7B, the exemplary quad-spot laser beam pattern 730 in FIG. 7A has the benefit of providing a more stable thermal profile in the vicinity of the junction as compared to the dual-spot laser beam pattern 740 of FIG. 7B, due to a more even spatial distribution of laser spots around the junction. However, the dual-spot laser beam may be utilized with a lower laser energy level as compared to the quad-spot laser beam pattern 730 of FIG. 7A, as the exemplary quad-spot laser beam pattern 730 comprises additional laser spots to distribute and apply laser energy over a wider area, which therefore requires more laser power to achieve the same temperature in the vicinity of the Josephson junction 723. In any event, the resistance of a Josephson junction may be adjusted to a target junction resistance by a number of factors including, e.g., laser power, exposure time, laser illumination pattern, laser-to-junction alignment, all of which is precisely controlled for proper laser tuning.

It is to be understood that FIGS. 7A-7I illustrate exemplary techniques for laser annealing Josephson junctions of superconducting qubits with having single or dual Josephson junction geometries using a wide range of customized structured laser beam illumination patterns. For example, customized structured laser beam illumination patterns can be generated, as desired, using variable laser beam spot sizes, variable beam spot intensity profiles (e.g., Gaussian profiles, annular profiles with different spiral phase distributions, etc.), various laser beam spot layout patterns (e.g., square, rectangular, linear lattice configurations, or a single laser spot, or any combination thereof) with various laser beam spot spacings, etc. The customized structured laser beam illumination patterns are configured to provide a wide range of customizable thermal profiles that can be generated and utilized for laser annealing Josephson junctions for various types of quantum device geometries comprising single or multi-Josephson junction geometries.

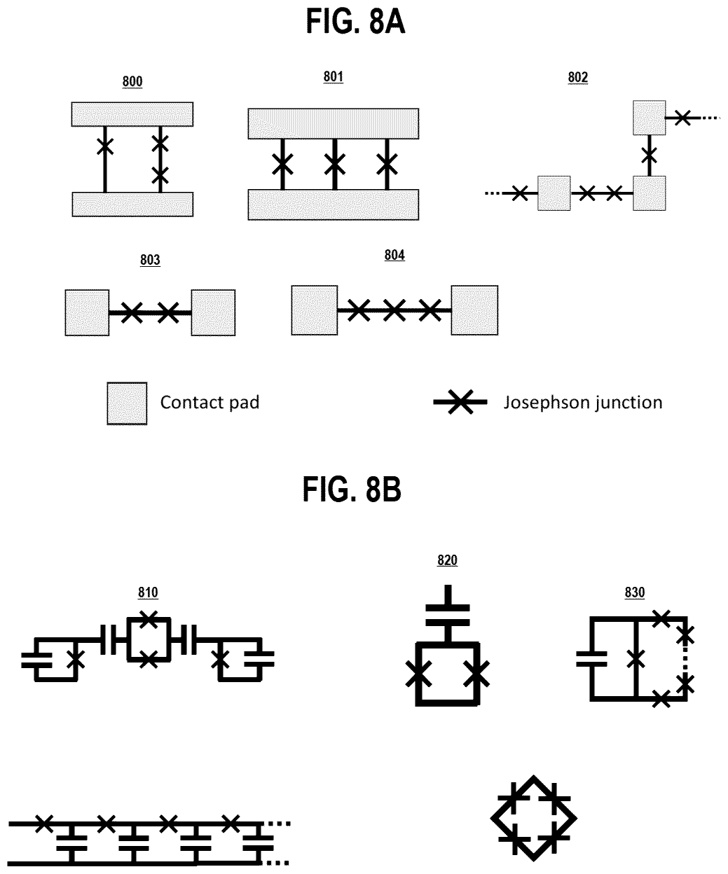

FIG. 8A schematically illustrates different geometries and layouts of Josephson junctions, which may comprise portions of superconducting quantum devices, and which can be laser annealed using different laser beam illumination patterns, according to exemplary embodiments of the disclosure. For example, FIG. 8A illustrates various quantum devices having different Josephson junction geometries, e.g., a quantum device 800 having a network of Josephson junctions comprising two series Josephson junction connected in parallel with a single Josephson junction, quantum device 801 having three Josephson junction connected in parallel, and quantum devices 802, 803, and 804.

In addition, FIG. 8B schematically illustrates superconducting quantum devices having different geometries and layouts of Josephson junctions, which can be laser annealed using different laser beam illumination patterns, according to exemplary embodiments of the disclosure. For example, FIG. 8B schematically illustrates a quantum device 810 comprising a flux-tunable coupler and two qubits that are coupled to the flux-tunable coupler, wherein the flux-tunable coupler is configured to mediate entanglement gate operations between two qubits. In addition, FIG. 8B schematically illustrates a quantum device 820 comprising a charge qubit, a quantum device 830 comprising a fluxonium qubit comprising multiple Josephson junctions, a quantum device 840 comprising a parametric modulator or parametric amplifier circuit configuration, and a quantum device 850 comprising a Josephson junction ring modulator.

For a laser anneal process, a given Josephson junction or group (network) of Josephson junction are thermally annealed using laser beam illumination, and then probed to determine the changes in junction resistance. Each Josephson junction or group of junctions to be separately tuned will span a pair of probing contact pads (as shown in FIG. 8A). The probing (contact) pads may comprise coplanar capacitor pads as in superconducting qubits, or may be otherwise incorporated into the structure. FIG. 8A illustrates how a multi-junction quantum device may arrange groups of qubits to span probing pads. The quantum device 800 comprises a network of three Josephson junctions (two junctions in series, in parallel with a third single junction), which may be measured via contact pads after laser-annealing the junctions. The Josephson junction network of the quantum device 800 may be implemented, e.g., in flux qubits.

For the quantum device 801, the three Josephson junctions and contact pads are arranged so that the combined parallel resistance of the three Josephson junctions may be measured after being laser anneal. The exemplary quantum devices 803 and 804 illustrate how contact pads may be placed to allow resistance measurements of a series combination of two or three Josephson junctions. The exemplary quantum device 802 comprises an extended chain of Josephson junctions in which contact pads are placed at intervals to permit resistance measurements of single Josephson junctions or groups of serially connected Josephson junctions within the chain.

Similarly, FIG. 8B illustrates schematically a variety of relevant superconducting devices containing SQUID loops or other multi-junction networks. The exemplary quantum circuit 810 comprises a pair of single-junction transmon qubits that are coupled by a flux-tunable coupler containing a SQUID loop. The exemplary quantum circuit 820 illustrates a SQUID loop and capacitance, as may be used in a flux-tunable charge qubit. The exemplary quantum circuit 830 illustrates a multi-junction series network in parallel with a single junction and capacitance, as may be used in fluxonium qubits. The exemplary quantum device 840 illustrates an extended chain network of junctions and capacitances as may be used in a traveling-wave parametric amplifier. The exemplary quantum device 850 comprises a ring network of Josephson junctions as may be used in a Josephson ring modulator circuit. Many related quantum devices including flux qubits, phase qubits, tunable-coupler qubits, flux-tunable couplers, quantum amplifiers and quantum-limited modulation circuits comprise variants of the exemplary schematic arrangements shown in FIG. 8B, wherein such quantum devices may also include other circuit elements such as capacitors or linear inductors that are not specifically shown in FIG. 8A or 8B.

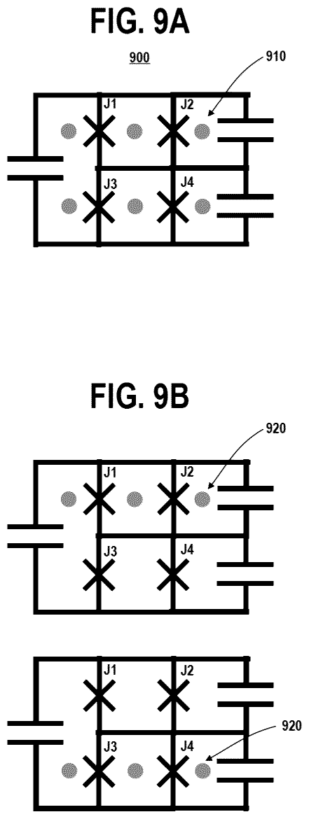

FIG. 9A schematically illustrates an exemplary superconducting quantum device having multiple Josephson junctions which can be concurrently laser annealed using a laser beam illumination pattern, according to an exemplary embodiment of the disclosure. In particular, FIG. 9A schematically illustrates a multi-junction qubit device 900 (e.g., tunable coupler qubit) having four (4) Josephson junctions J1, J2, J3, and J4, which can be concurrently laser annealed (one iteration) using a laser beam illumination pattern 910 comprising six (6) laser beams spots arranged in a rectangular layout, and properly aligned to the four Josephson junctions J1, J2, J3, and J4, as schematically shown in FIG. 9A.

On the other hand, FIG. 9B schematically illustrates the exemplary superconducting quantum device 900 in which four (4) Josephson junctions J1, J2, J3, and J4, can be laser annealed in two sequential iterations using a laser beam illumination pattern 920 comprising three laser beam spots that are linearly arranged. For example, as schematically illustrated in FIG. 9A, a process for laser annealing the superconducting quantum device 900 can include two iterations, e.g., a first laser anneal iteration to laser tune the two upper Josephson junctions J1 and J2 using the three-spot laser beam illumination pattern 920, followed by a second laser anneal iteration to laser tune the two lower Josephson junctions J3 and J4 using the same three-spot laser beam illumination pattern 920. By this method of annealing in succession, all junctions receive equal total thermal treatment and thus will tune at similar progression rates.

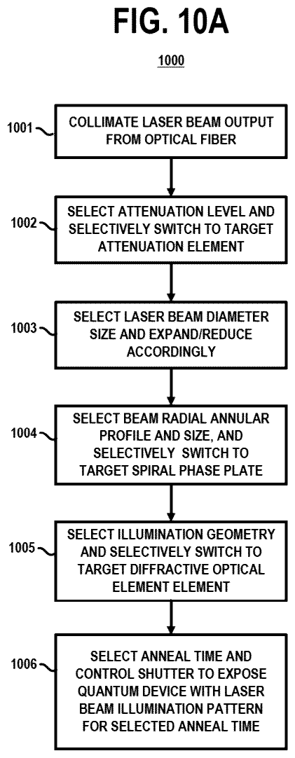

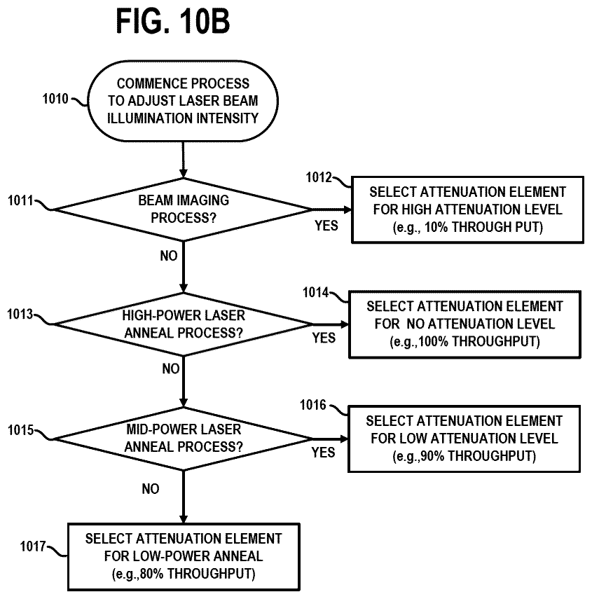

FIG. 10A illustrates a flow diagram of a method 1000 for configuring a laser microscope to generate a laser beam illumination pattern for performing a laser annealing operation, according to an exemplary embodiment of the disclosure. In some embodiments, FIG. 10A illustrates a method for configuring the operation of the exemplary laser microscope 300 of FIG. 3A. The laser microscope 300 receives a laser beam that is output from the optical fiber 226 and collimated the received laser beam using the fiber collimator 312 (block 1001). A desired laser illumination intensity (or attenuation level) is selected and the laser microscope 300 is configured to selectively place a target optical attenuation element in an optical path of the collimated laser beam to adjust the laser illumination intensity of the collimated laser beam based on the selected optical attenuation element (block 1002). As noted above, in some embodiments, the switchable attenuation device 320 of the laser microscope 300 is controlled to selectively switch to the target optical attenuation element among a plurality of different attenuation elements of the switchable attenuation device 320. A desired laser beam diameter is selected and the laser microscope 300 is configured to generate a collimated laser beam having a target beam diameter (block 1003).

Next, in instances where the target laser beam illumination pattern should include one or more laser beam spots with annular profiles, a desired radial annular profile is selected and the laser microscope 300 is configured to selectively place a target spiral phase plate in the optical path of the collimated laser beam to generate an annular laser beam based on the collimated laser beam (block 1004). As noted above, in some embodiments, the switchable spiral phase plate device 360 of the laser microscope 300 is controlled to selectively switch to the target spiral phase plate among a plurality of different spiral phase plates of the switchable spiral phase plate device 360.

Moreover, in instances where the target laser beam illumination pattern should include multiple laser beam spots (e.g., two or more laser beam spots in a linear, rectangular, or square configuration), a desired diffractive optical element is selected, which comprises a diffraction grating that is configured to generate the desired multi-spot illumination geometry, and the laser microscope 300 is configured to selectively place a target diffractive optical element in the optical path of the collimated laser beam to split the collimated laser beam into a plurality of laser beams that are used for generating the desired multi-spot illumination geometry (block 1005). As noted above, in some embodiments, the switchable DOE device 380 of the laser microscope 300 is controlled to selectively switch to the target diffractive optical element amount a plurality of different diffractive optical elements of the switchable DOE device 380. Finally, a target anneal time is selected for annealing a superconducting quantum device having one or more Josephson junctions, and the electronic shutter 350 of the laser microscope 300 is controlled to expose the superconducting quantum device with a beam illumination pattern for the target anneal time to laser anneal the one or more Josephson junctions of the superconducting quantum device (block 1006).

FIG. 10B illustrates a flow diagram of a method for configuring a laser microscope to adjust a laser illumination intensity for different operation conditions, according to an exemplary embodiment of the disclosure. In some embodiments, FIG. 10B illustrates a method for configuring the operation of the exemplary laser microscope 300 of FIG. 3A. The laser microscope 300 receives a control signal to commence a process for adjusting a laser beam illumination intensity (block 1010). In some embodiments, as noted above, the switchable attenuation device 320 of the laser microscope 300 is controlled to selectively switch to a target optical attenuation element among a plurality of different attenuation elements of the switchable attenuation device 320.

For example, if an illumination beam pattern imaging process is to be performed (affirmative determination in block 1011) for, e.g., aligning an illumination beam pattern to a center of a FOV of the laser microscope unit 300, the laser microscope 300 is configured to selectively place a target optical attenuation element in an optical path of the collimated laser beam to achieve a relatively high attenuation level, e.g., 10% throughput (block 1012), which is sufficient to properly image a given laser beam illumination pattern (via a camera of the laser microscope 300) without exposing the sample with high laser beam intensity. In addition, the high attenuation level of the laser beam is performed to avoid saturating the camera 302 of the laser microscope unit 300 that that the camera 302 can take images of elements within the FOV of the laser microscope unit 300 for purposes of enabling computer vision and pattern recognition processes.

On the other hand, if a high-power laser anneal process is to be performed (affirmative determination in block 1013), the laser microscope 300 is configured to selectively place a target optical attenuation element in the optical path of the collimated laser beam to achieve very little or no attenuation, e.g., 100% throughput, of the collimated laser beam (block 1014). In some embodiments, a higher-power anneal process is performed using laser power at around 2.0 watts. Next, if a mid-power laser anneal process is to be performed (affirmative determination in block 1015), the laser microscope 300 is configured to selectively place a target optical attenuation element in the optical path of the collimated laser beam to achieve relatively low attenuation, e.g., about 90% throughput, of the collimated laser beam (block 1016). In some embodiments, a mid-power anneal process is performed using laser power at around 1.8 watts. On the other hand, if a low-power laser anneal process is to be performed, the laser microscope 300 is configured to selectively place a target optical attenuation element in the optical path of the collimated laser beam to achieve relatively higher attenuation, e.g., about 80% throughput, of the collimated laser beam (block 1017). In some embodiments, a low-power anneal process is performed using laser power at around 1.6 watts or less. In some embodiments, a laser power setting of the laser unit 200 (e.g., FIGS. 2 and 3A) can be set to provide a coarse laser power level setting, while the switchable attenuation device 320 of the laser microscope 300 is controlled to selectively switch to a target optical attenuation element among a plurality of different attenuation elements of the switchable attenuation device 320 to provide a fine adjustment of the laser beam power (or illumination intensity).

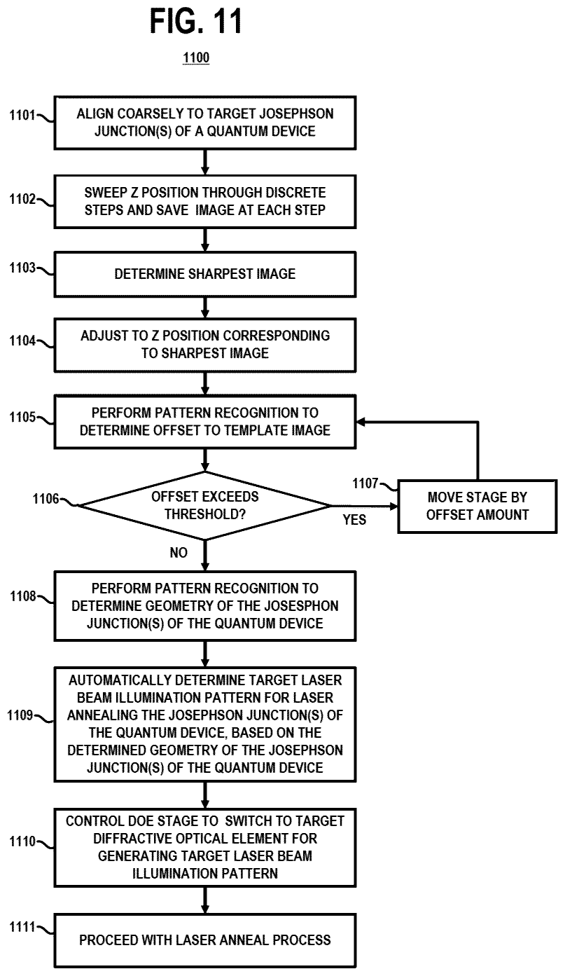

FIG. 11 illustrates a flow diagram of a method for automated selection of a laser beam illumination pattern for laser tuning a quantum device, according to an exemplary embodiment of the disclosure. More specifically, FIG. 11 illustrates a process 1100 for automatically selecting a target laser beam illumination pattern for laser annealing a superconducting quantum device which comprises a geometry of one or more Josephson junctions, wherein the target illumination beam pattern is selected based on the geometry of the one or more Josephson junctions of the superconducting quantum device. An initial phase of the method 1100 involves performing a coarse alignment in which, e.g., an X-Y-Z stage of a prober unit is controllably operated to align the target Josephson junctions(s) of the superconducting quantum device with a center of the FOV of the laser microscope unit (block 1101). The prober unit is then controlled to sweep the Z position of the X-Y-Z stage through a series of discrete steps (positions), and the camera 302 of the laser microscope unit 300 is controlled to capture and save a digital image of the sample (sample image) in the FOV at each Z position (block 1102).

The automated process then determines a sharpest sample image among the plurality of sample images taken at the different Z positions (block 1103). In some embodiments, the sharpest sample image is determined using, e.g., an edge detection process to identify the sample image with the sharpest edges (e.g., sharpest edges of contact pads to which the electrical probes will make contact). The X-Y-Z stage is then controlled to move to the target Z position corresponding to the sharpest sample image (block 1104).

A pattern recognition operation is then performed to determine an amount of offset (if any) between the sample image taken of the target Josephson junction(s) in the FOV and a template image of the Josephson junction(s) aligned to the center of the FOV (block 1105). In some embodiments, the pattern recognition operation may be performed using a cross-correlation between the sample image and the template image to quantify the quality of the match, and the corresponding amount of offset (if any) required to optimize the match.

A determination is then made as to whether the offset as determined exceeds an offset threshold (block 1106). For example, such a determination can be made to determine whether the sample image of the Josephson junction(s) in the FOV is misaligned in the X direction, the Y direction, or in both the X and Y directions, by some offset amount which exceeds an offset threshold. If the X offset and/or Y offset is determined to exceed the offset threshold (affirmative determination in block 1106), the X-Y-Z stage 142 is controllably moved in the X and/or Y direction by the determined offset amount to correct for the misalignment in the X direction and/or Y direction (block 1107), and the pattern recognition and offset determination steps (blocks 1105 and 1106) are repeated.

Once the sample image of the Josephson junction(s) in the FOV is determined to be aligned to the template image, the process proceeds to perform a pattern recognition process to determine a geometry of the one or more Josephson junctions of the superconducting quantum device (block 1108). The process then determines a target laser beam illumination pattern for laser annealing the one or more Josephson junctions of the superconducting quantum device, based on the determined geometry of the one or more Josephson junctions of the superconducting quantum device (block 1109). The process then proceed to configure the laser microscope unit generate the target laser beam illumination pattern by, e.g., controlling the switchable DOE device configuring the laser microscope to select one of a plurality of different diffractive optical elements to place in an optical path of a collimated laser beam to split the collimated laser beam into a plurality of laser beams that are further optically manipulated (e.g., focused by the objective lens) to generate the target laser beam illumination geometry for proceeding with a laser anneal process (block 1111) to laser anneal the Josephson junction(s) of the given quantum device.

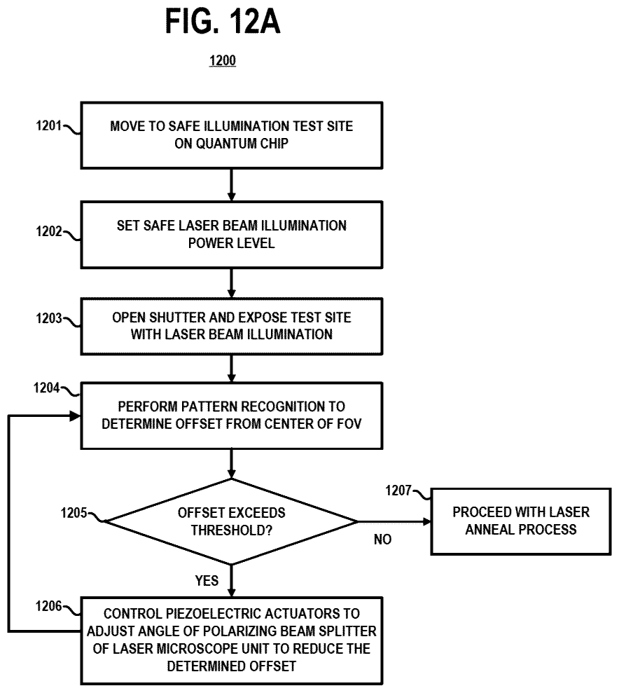

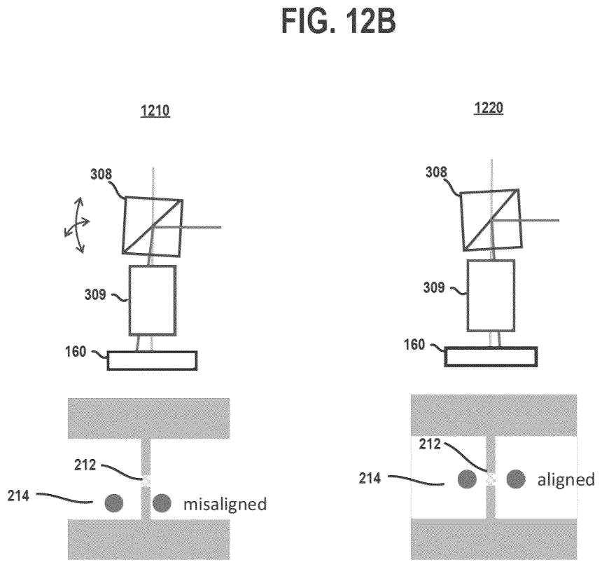

FIGS. 12A and 12B illustrate methods for automated alignment of a laser beam illumination pattern. In particular, FIG. 12A illustrates a flow diagram of a method 1200 for automatically aligning a laser beam illumination pattern to a field of view of a laser microscope unit, according to an exemplary embodiment of the disclosure. As an initial step, the XYZ stage of the prober unit is controlled to move the FOV of the laser microscope unit 300 to a safe illumination test site on the quantum chip (block 1201) and the laser microscope unit 300 sets a safe laser beam illumination power level (block 1202). For example, as discussed above in conjunction with FIG. 10, when an illumination beam pattern imaging process is to be performed to align an illumination beam pattern to a center of a FOV of the laser microscope unit 300, the laser microscope 300 is configured to selectively place a target optical attenuation element in an optical path of the collimated laser beam to achieve a relatively high attenuation level, e.g., 10% throughput, The lower laser power level (or illumination intensity) is attenuated to a level that is sufficient to properly image a given laser beam illumination pattern (via a camera of the laser microscope 300) without saturating the camera 302 of the laser microscope unit 300 that that the camera 302 can take images of elements within the FOV of the laser microscope unit 300 for purposes of enabling computer vision and pattern recognition processes. In some embodiments, the relatively high attenuation level, e.g., 10% throughput is alone sufficient to attenuate the beam intensity to a level that prevents saturation of the camera 302. In other embodiments, the combination of the high attenuation level (e.g., using the attenuation element 514) and the notch filter element 307 is sufficient to attenuate the beam intensity to a level that prevents saturation of the camera 302.

The electronic shutter 350 of the laser microscope unit 300 is then controlled to expose the test site with a target laser beam illumination pattern (block 1203). A pattern recognition process is then performed to determine an amount offset, if any, of the laser beam illumination pattern from a center of the FOV of the laser microscope unit (block 1204). If the determined offset exceeds a specified offset threshold (affirmative determination in block 1205), the piezoelectric actuators of the polarizing beam splitter 308 are controlled to adjust an angle of the polarizing beam splitter 308 of the laser microscope unit 300 to reduce the determined offset (block 1206). Once the offset properly adjusted and no longer exceeds the specified offset threshold (negative determination in block 1205), the target laser beam illumination pattern is deemed to be aligned with the center of the FOV of the laser microscope unit 300, and the process can proceed with a laser anneal process (block 1207) using the target laser beam illumination pattern. The automated alignment process 1200 of FIG. 12A may be performed at specified intervals during an iterative laser annealing process ensure that the laser beam illumination patterns are properly aligned to the center of the FOV of the laser microscope unit 300.

Next, FIG. 12B schematically illustrates a method for automated alignment of a laser beam illumination pattern to a Josephson junction of a quantum device, according to an exemplary embodiment of the disclosure. In particular, FIG. 12B schematically illustrates an optical state 1210 in which there is misalignment between a Josephson junction 212 of a superconducting qubit device and a dual-spot laser beam illumination pattern 214. To correct for this misalignment, an automated process can be performed to correct the misalignment by (i) performing a computer vision process identify and locate the Josephson junction 212 and the dual-spot laser beam illumination pattern 214 in the FOV of the laser microscope unit, compute an amount of X-Y offset of the misalignment, and the control the piezoelectric actuator of the polarizing beam splitter 308 to precisely adjust a position of the polarizing beam splitter 308 to correct the X-Y offset in the FOV and thereby reach an optical state 1220 in which the dual-spot laser beam illumination pattern 214 is properly aligned to the Josephson junction 212.

Advantageously, the implementation of piezoelectric control fine adjustment of the positioning of the polarizing beam splitter 308 enable relatively faster alignment of a laser beam illumination pattern to one or more Josephson junctions of quantum device, without having to rely solely on X-Y correction of such misalignment using a wafer stage, which can be relatively slower and more imprecise, that the rapid and fine adjustment afforded by the piezo-controlled polarizing beam splitter 308, which can provide fast (less than 1 second) and accurate (less than 1 micron) adjustment of the piezo-controlled polarizing beam splitter 308 to correct for such misalignments.

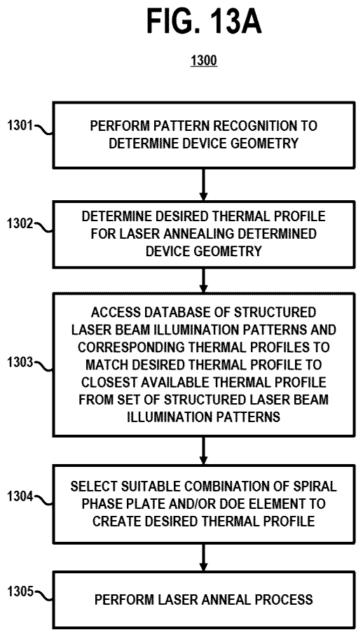

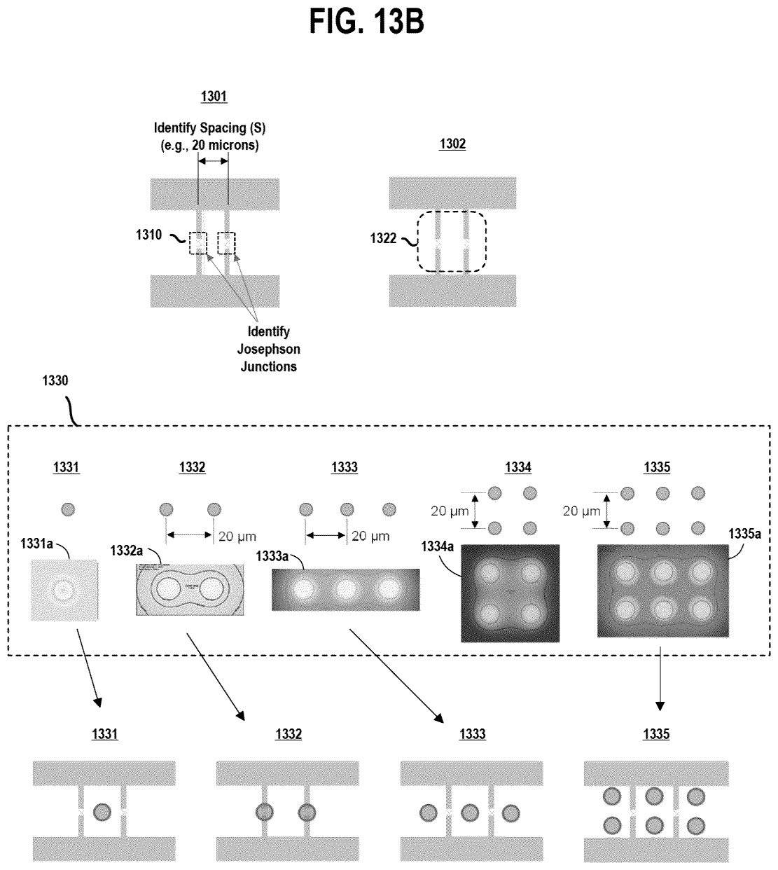

FIGS. 13A and 13B illustrate methods for automatically selecting a target laser beam illumination pattern for laser annealing a quantum device based on a target thermal profile, according to an exemplary embodiment of the disclosure. In particular, FIGS. 13A and 13B are directed to techniques for generating customized structured laser beam illumination patterns to achieve target thermal profiles for laser annealing arbitrary quantum devices (e.g., quantum devices such as shown in FIGS. 8A and 8B) having a geometry of Josephson junctions that is not known, a priori (e.g., no template laser beam illumination pattern exists which corresponds to the given Josephson junction geometry). In this case, a laser tuning calibration database may include various templates of structured laser beam illumination patterns and associated thermal profiles. A process for laser annealing a quantum device having a given multi-junction geometry generally comprises (i) performing pattern recognition to determine the device geometry of the Josephson junction(s) of the given quantum device, (ii) determining a target thermal profile that would be suitable to laser tune the Josephson junction(s) of the given quantum device based on the determined device geometry, (iii) searching the database to match (as close as possible) the determined target thermal profile to a template thermal profile in the database which has an associated structured laser beam illumination pattern, and (iv) selecting the structured laser beam illumination pattern associated with the matching thermal profile, and configuring a laser microscope to generate the selected laser beam illumination patten to laser anneal the given quantum device.

In particular, FIG. 13A illustrates a flow diagram of an automated process 1300 for selecting a laser beam illumination pattern for laser annealing a quantum device based on a target thermal profile, according to an exemplary embodiment of the disclosure. As an initial step, the process 1300 performs a pattern recognition process (via computer vision) to determine a device geometry of a quantum device comprising one or more Josephson junctions (block 1301). More specifically, the pattern recognition process is performed to determine a geometry (e.g., layout, arrangement, etc.) of the Josephson junction(s) of the quantum device.

The process 1300 proceeds to determine a target thermal profile for laser annealing the Josephson junction(s) of the quantum device, based on the determined geometry (block 1302). In some embodiments, the target thermal profile is determined based on a priori knowledge of an optimal thermal profile for a known device geometry. In other embodiments, for an unknown or arbitrary device geometry, the process 1300 is configured to analyze the device geometry and determine an optimal target thermal profile which would be suitable for laser annealing the given arbitrary device geometry.

Next, the process 1300 accesses a database of structured laser beam illumination patterns and corresponding thermal profiles to match a thermal profile in the database (e.g., a closest matching thermal profile) with the target thermal profile for the determined device geometry (block 1303). The process 1300 selects a laser beam illumination pattern in the database which corresponds to the matching thermal profile in the database (block 1304). The process 1300 then proceeds to select a suitable combination of a spiral phase plate and/or diffractive optical element, which is configured to generate the laser beam illumination pattern having the corresponding thermal profile which matches the target thermal profile (block 1304). The process 1300 proceeds to configure the laser microscope unit to generate the target laser beam illumination pattern for laser annealing the given quantum device (block 1305).

FIG. 13B schematically illustrates a process for selecting a laser beam illumination pattern for laser annealing a quantum device based on a target thermal profile, according to an exemplary embodiment of the disclosure. In particular, FIG. 13B schematically illustrates a process that is based on the process flow of FIG. 13A to select a laser beam illumination pattern for laser annealing a quantum device based on a target thermal profile. For example, FIG. 13B schematically illustrates a step (e.g., block 1301) in which the pattern recognition process determines a device geometry of a tunable qubit device comprising two Josephson junction devices 1310, and a step (e.g., block 1302) in which the process determines a target thermal profile 1322.

In addition, FIG. 13B illustrates an exemplary database 1330 which comprises a plurality of template laser beam illumination patterns 1331, 1332, 1333, 1334, and 1335 and associated thermal profiles 1331a, 1332a, 1333a, 1334a, and 1335a. It is to be noted that the term “thermal profile” as used herein refers to a temperature profile (or thermal signature) on a surface of a quantum chip that that is generated as a result of exposure by a given laser beam illumination pattern that is used to laser anneal one or more Josephsson junctions. The exemplary thermal profiles 1331a, 1332a, 1333a, 1334a, and 1335a are associated with the respective single-spot and multi-spot laser beam illumination patterns 1331, 1332, 1333, 1334, and 1335 in the sense that the exemplary thermal profile 1331a is correlated with the intensity profile of the single laser beam spot (e.g., single-spot pattern 1331), and that each of the exemplary thermal profiles 1332a, 1333a, 1334a, and 1335a is correlated with an aggregate/combined intensity profile of multiple laser beam spots of the respective laser beam illumination patterns 1332, 1333, 1334, and 1335, which results from a plurality of focused laser beam spots in close proximity to each other.

FIG. 13B further illustrates that given the target thermal profile 1322, any desired one of the laser beam illumination patterns and corresponding thermal profiles 1331, 1333 and 1335 can be selected to provide indirect heating of the two Josephson junctions 1310 of the qubit device, while the laser beam illumination pattern and corresponding thermal profile 1332 can be selected for direct illumination of the Josephson junctions 1310. In the illustrative embodiment of FIG. 13B, it may be that thermal profile 1335, corresponding to indirect heating of the two junctions with the desired thermal pattern 1322, is the closest match and the 6-spot pattern in 1335 may be implemented for the anneal.

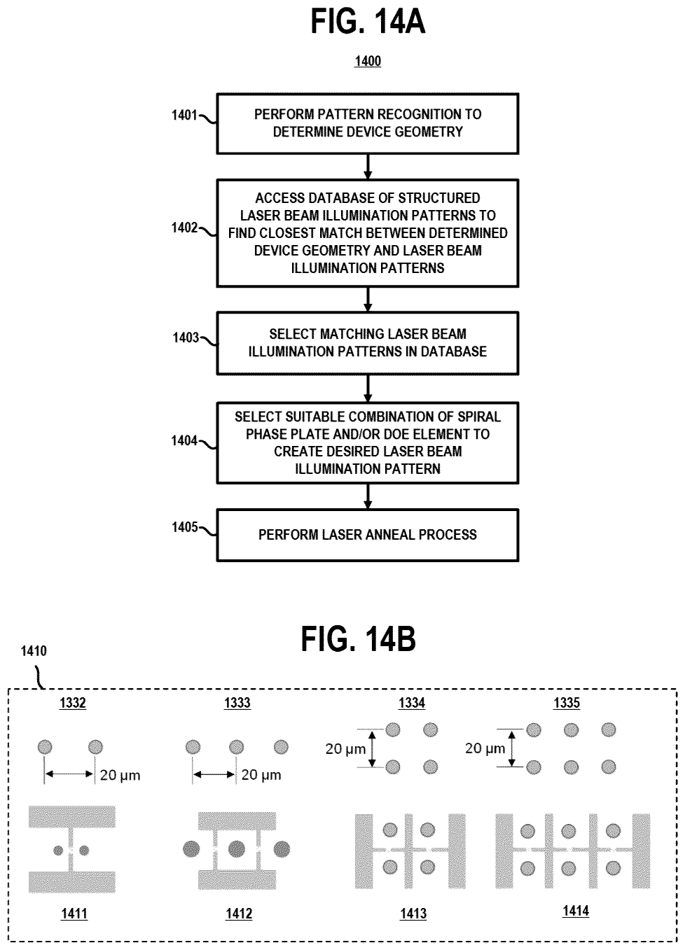

FIGS. 14A and 14B illustrates methods for automatically selecting a target laser beam illumination pattern for laser annealing a quantum device based on a matching template device geometry, according to an exemplary embodiment of the disclosure. In particular, FIGS. 14A and 14B are directed to techniques for generating customized structured laser beam illumination patterns that correspond to quantum devices having Josephson junction geometries that are known, a priori. In this case, a process for laser annealing a given quantum device having a given multi-junction geometry generally comprises (i) performing pattern recognition to determine a geometry of the Josephson junction(s) of the given quantum device, (ii) searching a database to match the determined geometry of the Josephson junction(s) of the given quantum device with a template geometry which has an associated structured laser beam illumination pattern, and (iii) selecting the structured laser beam illumination pattern that is associated with the matching template geometry, and configuring a laser microscope is configured to generate the selected structured laser beam illumination pattern to laser anneal the Josephson junctions of the quantum device.

particular, FIG. 14A illustrates a flow diagram of an automated process 1400 for selecting a laser beam illumination pattern for laser annealing a quantum device based on based on a matching template device geometry, according to an exemplary embodiment of the disclosure. As an initial step, the process 1400 performs a pattern recognition process (via computer vision) to determine a device geometry of a quantum device comprising one or more Josephson junctions (block 1401). More specifically, the pattern recognition process is performed to determine a geometry (e.g., layout, arrangement, etc.) of the Josephson junction(s) of the quantum device.

The process 1400 proceeds to access a database of structured laser beam illumination patterns and corresponding template device geometries to match the determined geometry of the superconducting quantum device to a template device geometry in the database (block 1402). The process 1400 then selects a laser beam illumination pattern in the database which corresponds to the matching template device geometry (block 1403). The process 1400 then proceeds to select a suitable combination of a spiral phase plate and/or diffractive optical element, which is configured to generate the laser beam illumination pattern that corresponds to the matching template device geometry (block 1404). The process 1400 proceeds to configure the laser microscope unit to generate the target laser beam illumination pattern for laser annealing the given quantum device (block 1405).

FIG. 14B schematically illustrates process for selecting a laser beam illumination pattern for laser annealing a quantum device based on based on a matching template. In particular, FIG. 14B schematically illustrates an exemplary database 1410 comprising a plurality of laser beam illumination patterns 1331, 1332, 13333, and 1334 (which are the same as those shown in FIG. 13B) and corresponding template device geometries 1411, 1412, 1413, and 1414. In some embodiments, the process of block 1402 in FIG. 14A can be implemented by accessing the exemplary data base 1410 of FIG. 14B to identify template device geometry 1411, 1412, 1413, or 1414 which matches determined geometry of the superconducting quantum device, and then identify the corresponding laser beam illumination pattern 1331, 1332, 13333, or 1334 which can be used to laser anneal the given quantum device. This direct matching method is contingent upon a successful database match of the junction geometry to an existing database element, or to find the closest corresponding match to an existing database element within a tolerance bound, which may be defined by an acceptable bound of a cross-correlation figure of merit, or, for example, the relative spacing between the junctions in the device to be annealed, by identifying the locations of the junctions and their relative spacings on the superconducting quantum device. In this way, the spacing between the illumination patterns can be ensured to uniformly anneal the specific junction geometry.

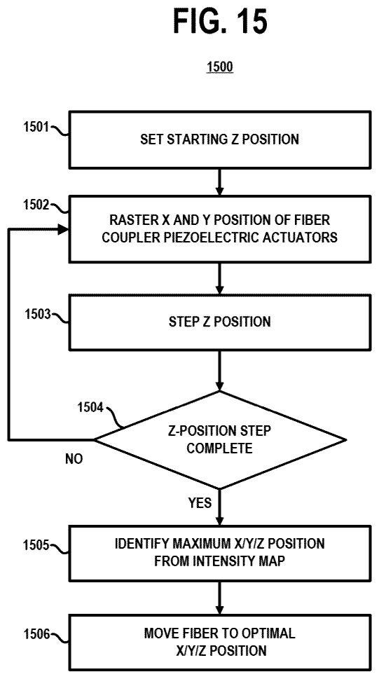

FIG. 15 illustrates a flow diagram of a method that is implemented by a laser unit for optically coupling a laser beam to an optical fiber, according to an exemplary embodiment of the disclosure. More specifically, in some embodiments, FIG. 15 illustrates a process 1500 that can be implemented by the laser unit 200 of FIG. 2 to optimize the optical coupling of the output of the objective lens 281 to the input end of the optical fiber 226 by utilizing the XYZ piezoelectric actuators 290 to adjust the position of the fiber optic ferrule 282 to ensure that the input end of the optical fiber 226 is located at or near the focal point of the objective lens 281. As an initial step, the process 1500 controls the Z piezoelectric actuator 290 to set a starting Z position of fiber optic ferrule 282. The process 1500 then proceeds to control the XY piezoelectric actuators 290 to raster the X and Y position of the fiber optic ferrule 282 (block 1502). When all Z position steps have not been completed (negative determination in block 1504), the process 1500 proceeds to step to a next Z position (block 1503), and then proceeds to raster the X and Y position of the fiber optic ferrule 282 at the next Z position (return to block 1502). When all Z position steps have been completed (affirmative determination in block 1504), the process 1500 determines the optimal X-Y-Z position that provides a maximum optical coupling (block 1505), and then proceeds to adjust the position of the fiber optic ferrule 282 to the determined optimal X-Y-Z position (block 1506) to achieve an optimal optical coupling of the laser beam into the optical fiber 226. It is to be noted that the process 1500 of FIG. 15 can be performed as specified intervals during an iterative laser annealing process.

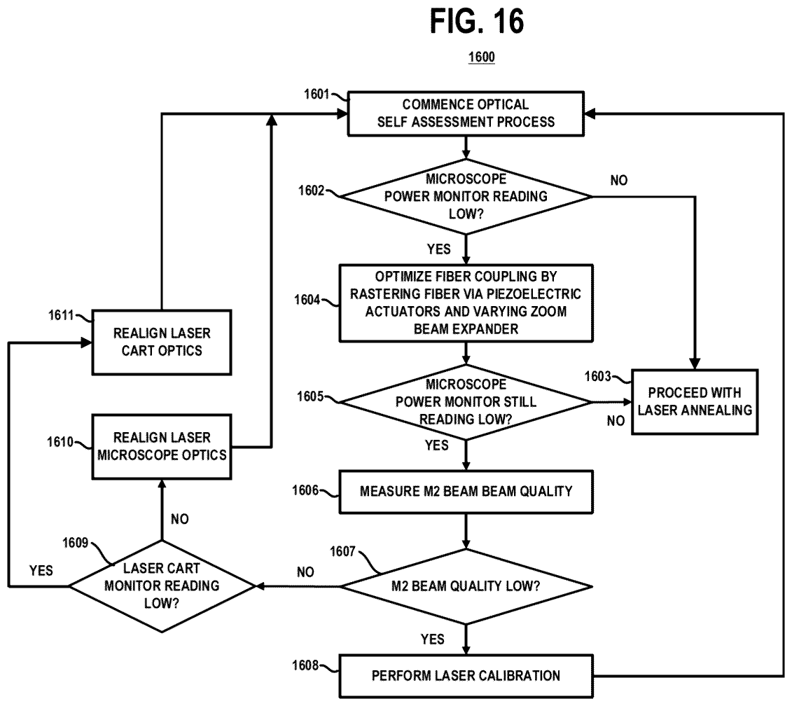

FIG. 16 illustrates a flow diagram of a method for monitoring a power level and beam quality of a laser beam that is generated by a laser unit, according to an exemplary embodiment of the disclosure. More specifically, in some embodiments, FIG. 16 illustrates an exemplary process 1600 that can be initiated by a laser unit control module of the laser unit 200 of FIG. 2 to perform an optical self-assessment of the laser unit (block 1601). This process 1600 can be performed at regular intervals (based on some optional time delay), or may be performed before each annealing step to ensure a high-quality laser beam for laser annealing is being coupled into the optical fiber 226.

As an initial step, a determination is made as to whether the power monitor 340 of the laser microscope 300 is reading low (block 1602). If the power monitor 340 of the laser microscope 300 is not reading a low laser power (negative determination in block 1602), the laser annealing process can proceed (block 1603). On the other hand, if the power monitor 340 of the laser microscope 300 is reading a low laser power level (affirmative determination in block 1602), the process 1500 of FIG. 15 is performed to optimize the optical coupling of the fiber coupler 280 of the laser unit 200 and by controlling the variable beam expander 250 to adjust the diameter of the laser beam (block 1604). If the power monitor 340 of the laser microscope 300 is still reading a low laser power (affirmative determination in block 1605), the beam quality monitoring system 270 is utilized to measure the M2 beam quality of the laser beam (block 1606).

In an event that the M2 beam quality is determined to be low (affirmative determination in block 1607), a laser calibration process is performed (block 1608), and the optical self-assessment process (block 1601) is commenced again following completion of the laser calibration process (block 1608). In some embodiments, the laser calibration process comprises a thermal calibration process to ensure adequate temperature stability of the nonlinear crystal utilized in the second-harmonic generation process. On the other hand, if the M2 beam quality is not determined to be low (negative determination in block 1607), a determination is made as to whether the laser unit power monitor 240 is reading low (block 1609). If the laser unit power monitor 240 is not reading low (negative determination in block 1609), the optics of the laser microscope unit 300 are realigned (block 1610), and the optical self-assessment process (block 1601) is commenced again after realignment of the optics of the laser microscope unit 300. On the other hand, if the laser unit power monitor 240 is reading low (affirmative determination in block 1609), the optics of the laser unit 200 are realigned (block 1611), and the optical self-assessment process (block 1601) is commenced again after realignment of the optics of the laser unit 200.

In other embodiments, the exemplary laser annealing systems and techniques as described above can be utilized to perform laser tuning calibration methods to obtain tuning calibration data by performing trial laser anneal operations on representative hardware comprising Josephson junction (e.g., qubits with Josephson junctions), and utilize the tuning calibration data to determine tuning curves and associated tuning calibration parameters such as tuning rates and maximum tuning ranges of Josephson junctions for various combinations of laser power settings, anneal times, and laser beam illumination patterns, to enable bidirectional tuning of Josephson junctions. In some embodiments, the tuning calibration data is utilized to compute/estimate tuning curves that provide information for bidirectional tuning of junction resistances of Josephson junctions in forward directions (e.g., increase junction resistance) and reverse directions (e.g., decrease junction resistance), as desired, based on appropriate selections of annealing power, anneal time, and laser beam illumination pattern. For example, bidirectional tuning curves can be utilized to determine calibration parameters (e.g., tuning rates, maximum/minimum tuning ranges, laser beam illumination patterns) for different laser tuning regimes to thereby enable bidirectional tuning of Josephson junctions through positive junction resistance shifts and/or negative junction resistance shifts, as needed to reach target junction resistances of the Josephson junctions.

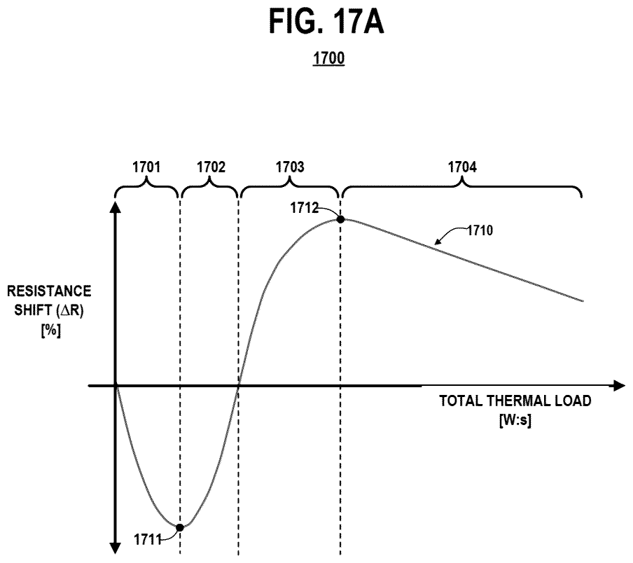

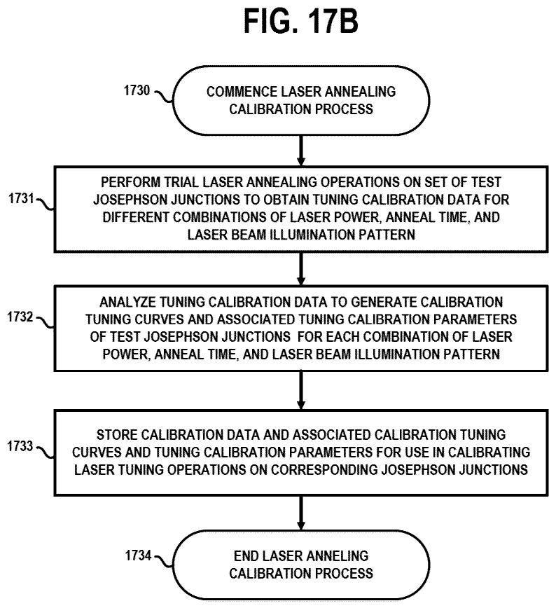

FIG. 17A graphically illustrates a bidirectional tuning curve for laser tuning Josephson junctions, according to an exemplary embodiment of the disclosure. In particular, FIG. 17A illustrates a graph 1700 of an exemplary bidirectional tuning curve 1710, wherein the graph 1700 illustrates an amount of junction resistance shift (AR) % as function of total thermal load in watt-seconds (i.e., joules) for four different tuning regimes (alternatively, tuning profiles) including a negative tuning regime 1701, a forward-shift tuning regime 1702, a positive tuning regime 1703, and a reverse-shift tuning regime 1704 (alternatively and synonymously referred to herein as negative tuning profile 1701, a forward-shift tuning profile 1702, a positive tuning profile 1703, and a reverse-shift tuning profile 1704). It is to be noted that term ΔR denotes a difference between an initial junction resistance (denoted Rᵢₙᵢₜᵢₐₗ) of given Josephson junction before laser annealing, and a current junction resistance (denoted R_{current}) of the given Josephson junction after performing a laser annealing operation at given combination of a laser power setting, anneal time, and laser beam illumination pattern, i.e.,

ΔR=R_{current}−Rᵢₙᵢₜᵢₐₗ.

In this regard, the Y-axis of the graph 1700 represents a “resistance shift percentage” which is determined as

$$Δ R \% = \frac{Δ R}{{R}_{initial}} \times 100 \% = \frac{{R}_{current} - {R}_{initial}}{{R}_{initial}} \times 100 \% .$$

It is to be noted that the term “current junction resistance” as used herein and in conjunction with the notation R_{current} is meant to denote a junction resistance measured in the sense of occurring in or existing at a present time, or a most recently measured junction resistance.

The negative tuning regime 1701 of the bidirectional tuning curve 1710 illustrates that a controlled negative junction resistance shift can be achieved by laser annealing a Josephson junction at a relatively low laser anneal power (e.g., about 20 joules or less) for a given anneal time. In the negative tuning regime 1701, the junction resistance is shown to monotonically decrease to a maximum negative junction resistance shift (e.g., ΔR of approximately −6.0%) as represented by point 1711 on the bidirectional tuning curve 1710. In other words, the point 1711 represent a maximum negative tuning range (or maximum negative resistance shift) for the exemplary bidirectional tuning curve 1710. In addition, FIG. 17A illustrates that the negative tuning regime 1701 comprises a tuning rate which corresponds to the slope of the bidirectional tuning curve 1710 in the negative tuning regime 1701 (e.g., a negative tuning rate corresponding to a negative slope).

The forward-shift tuning regime 1702 of the bidirectional tuning curve 1710 illustrates that a controlled positive junction resistance shift can be achieved by laser annealing a Josephson junction at a relatively higher laser anneal power (e.g., about 50 joules or less) for a given anneal time. In the forward-shift tuning regime 1702, the junction resistance is shown to monotonically increase over time by applying the appropriate laser anneal power. In some embodiments, the forward-shift tuning regime 1702 can be utilized to perform a corrective laser tuning operation to correct for an overshoot (e.g., passed negative target resistance shift) that occurs when tuning a given Josephson junction in the negative tuning regime 1701.

The positive tuning regime 1703 of the bidirectional tuning curve 1710 illustrates that a controlled positive junction resistance shift can be achieved by laser annealing a Josephson junction at a relatively higher laser anneal power (e.g., about 100 joules) for a given anneal time. In the positive tuning regime 1703, the junction resistance is shown to monotonically increase to a maximum junction resistance shift (e.g., ΔR=+15.0%) as represented by point 1712 on the bidirectional tuning curve 1710. In other words, the point 1712 represent a maximum positive tuning range (or maximum positive resistance shift) for the exemplary bidirectional tuning curve 1710. In addition, FIG. 17A illustrates that the positive tuning regime 1703 comprises a tuning rate which corresponds to the slope of the bidirectional tuning curve 1710 in the positive tuning regime 1703 (e.g., a positive tuning rate corresponding to a positive).

The reverse-shift tuning regime 1704 of the bidirectional tuning curve 1710 illustrates that a controlled negative junction resistance shift can be achieved by laser annealing a Josephson junction at a relatively higher thermal load (e.g., greater than 100 joules) using, e.g., a laser power level greater than 2.0 watts and an anneal time that is greater than 100 seconds. In the reverse-shift tuning regime 1704, the junction resistance is shown to monotonically decrease over time by applying the appropriate laser anneal power and anneal time. In some cases, in the reverse-shift tuning regime 1704, the junction resistances of Josephson junctions can continue to decrease in the negative direction until reaching, and even decreasing below, the initial junction resistances of the Josephson junctions. In some embodiments, the reverse-shift tuning regime 1704 can be utilized to perform a corrective laser tuning operation to correct for an overshoot (e.g., passed positive target resistance shift) that occurs when tuning a given Josephson junction in the positive tuning regime 1703. In particular, the reverse-shift tuning regime 1704 can be utilized to correct tuning errors and imprecisions adaptively, by changing the tuning targets within the bounds available with the reverse-shift tuning regime 1704. In some instances, the reverse-shift tuning regime 1704 may be used at the outset to achieve negative resistance tuning (e.g., −ΔR %), although at the expensive of higher laser powers and anneal times, which can be prohibitive.

As noted above, exemplary calibration techniques are configured to obtain tuning calibration data by performing trial laser anneal operations on representative hardware comprising Josephson junction (e.g., qubits with Josephson junctions), and utilize the tuning calibration data to determine various laser tuning calibration parameters including, e.g., tuning rates and maximum tuning ranges for various combinations of different laser power settings, anneal times, and laser beam illumination patterns, to enable bidirectional tuning of Josephson junctions. FIG. 17B illustrates a flow diagram of a calibration process for obtaining calibration data for use in generating tuning curves and associated calibration data for bidirectional laser tuning of Josephson junctions, according to an exemplary embodiment of the disclosure.

Referring to FIG. 17B, a quantum chip is placed on the X-Y-Z stage 142 of the prober unit 140, and the control system 110 commences an automated calibration process (block 1730). The quantum chip comprises a set of test Josephson junctions which are representative of actual Josephson junctions that are to be laser tuned using the calibration data obtained from the calibration process. In some embodiments, the quantum chip is a test chip, e.g., a sister chiplet from a same wafer having quantum devices and Josephson junctions that were fabricated using the same fabrication processes (e.g., junction evaporation process) as the Josephson junctions on the actual quantum chip. In this regard, the Josephson junctions on the test chip (e.g., sister chiplet) are deemed to correspond to the Josephson junctions on the actual chip which are to be tuned by laser annealing operations that are configured using the calibration data obtained from the calibration operations performed on the test Josephson junctions on the test chip, since the test Josephson junctions and the actual Josephson junctions are fabricated using the same or similar processes. In this regard, the test Josephson junctions are assumed to have the same, or substantially the same, or similar laser tuning characteristics as the Josephson junctions on the actual chip which are to be tuned by laser annealing operations that are configured using the calibration data obtained from the calibration operations performed on the test Josephson junctions on the test chip.

In other embodiments, the calibration process may be implemented using a collection of test Josephson junction devices that reside on the same quantum chip which has the actual Josephson junctions that are to be tuned. For example, the collection of Josephson junctions can be a dedicated test array of Josephson junctions that are formed on the quantum chip and located, e.g., in the kerf of the quantum chip. In this regard, the collection of test Josephson junctions on the quantum chip correspond to the actual Josephson junctions on the same quantum chip, which are to be laser tuned by laser annealing operations that are configured using the calibration data obtained from the calibration operations performed on the test Josephson junctions on the same quantum chip. The test Josephson junctions may be arranged in groups such that their combined network resistances may be measured identically to the groups in the devices to be tuned on the quantum chip. For instance, pairs of Josephson junctions in parallel may be used to calibrate laser-tuning of SQUIDs. Since the collection of test Josephson junctions and the actual Josephson junctions (residing on the same quantum chip) are fabricated using the same fabrication processes, the test Josephson junctions and actual Josephson junction (to be laser tuned) will have the same, or substantially the same, or similar tuning characteristics.

The calibration process proceeds by performing a series of trial laser anneal operations on a set of test Josephson junctions to obtain calibration data for different combinations of a plurality of laser power settings, anneal times, and laser beam illumination patterns (block 1731). For example, in some embodiments, the calibration process is performed by selecting a plurality of discrete laser power settings, e.g., 1.2 watts (W), 1.60 W, 1.80 W, and 2.0 W, and a plurality of anneal times for each laser power setting, e.g., a set of anneal times 0.5 s, 1.0 s, 2.0 s, 5.0 s, 10.0 s, 20.0 s, and 100 s for each of the discrete laser power settings (e.g., 1.60 watts at anneal times of 0.5 s, 1.0 s, 2.0 s, 5.0 s, 10.0 s, 20.0 s, and 100 s, etc.). In addition, in some embodiments, each power/anneal time combination for the calibration process is performed using two or more different laser beam illumination patterns. For each combination of laser power, anneal time, and laser beam illumination pattern, laser annealing operations are performed on a respective group of trial Josephson junctions (e.g., 3-10 Josephson junctions per group) to obtain a statistically significant amount of tuning calibration data.

The calibration process analyzes the tuning calibration data to generate calibration tuning curves (e.g., bidirectional tuning curves) and associated calibration parameters (e.g., maximum tuning ranges, tuning rates, etc.) for the test Josephson junctions, for each combination of laser power, anneal time, and laser beam illumination pattern (block 1732). The tuning curves and associated calibration parameters for respective combinations of laser power/anneal time/laser beam illumination pattern, provide information to enable bidirectional tuning (e.g., negative resistance shift tuning, positive resistance shift tuning) in different tuning regimes. The calibration data, calibration tuning curves and associated calibration parameters (e.g., maximum tuning ranges, tuning rates, etc.) for each respective combination of laser power, anneal time, and laser beam illumination pattern are persistently stored (block 1733) and the calibration process terminates (block 1734). The persistently stored tuning curves and calibration parameters are subsequently utilized for calibrating laser tuning operations that are to be performed on Josephson junctions to tune the respective junction resistances to respective target junction resistances, using laser tuning processes discussed in further detail below.

The exemplary bidirectional tuning curves and associated tuning calibration parameters are utilized to calibrate laser annealing operations for tuning Josephson junctions to respective target junction resistances. For example, the bidirectional tuning curves and associated tuning calibration parameters can be used to calibrate the initial laser tuning operations (initial shots) that are performed on Josephson junctions to partially tune the Josephson junctions to respective target junction resistances by an amount that corresponds to an initial tuning resistance shift

ΔRᵢₙᵢₜᵢₐₗ=F×ΔR_{target}.

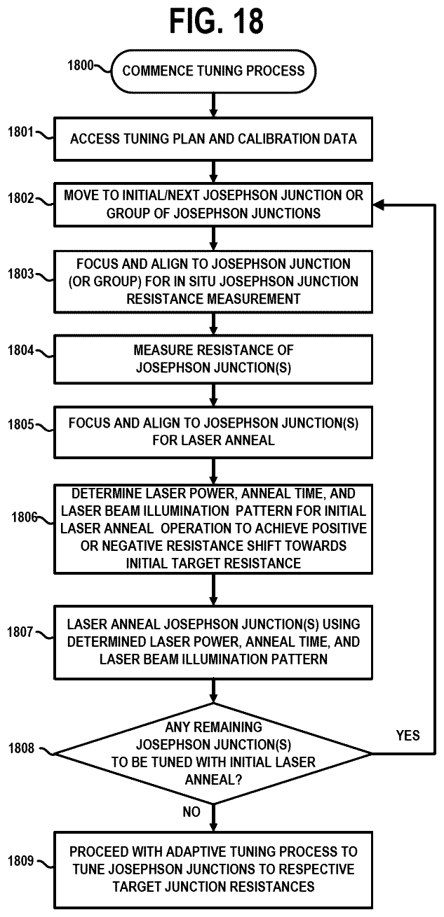

In some embodiments, an initial tuning factor of F≅50% is chosen to appreciably tune the Josephson junctions toward their target junction resistances R_{target}, while mitigating the risk of overshooting R_{target}. For example, FIG. 18 illustrates a flow diagram of a method for tuning Josephson junctions, according to an exemplary embodiment of the disclosure. In some embodiments, FIG. 18 illustrates an automated tuning process, which can be performed to laser tune Josephson junctions to respective R_{target} values and thereby tune superconducting qubits in a qubit lattice on a quantum chip to respective target transition frequencies as specified by a frequency tuning plan.

For example, a quantum chip is placed on the X-Y-Z stage 142 of the prober unit 140, and the control system 110 commences an automated laser tuning process (block 1800). The quantum chip comprises a plurality of superconducting qubits arranged in a given qubit lattice. The tuning process accesses a frequency tuning plan generated for the given qubit lattice, and tuning calibration data (e.g., bidirectional tuning curves and associated calibration parameters) associated with the Josephson junctions of the superconducting qubits (bock 1801). In some embodiments, the frequency tuning plan specifies respective R_{target} values for the Josephson junctions, as well as calibration parameters for determining suitable laser power settings, anneal times, and laser beam illumination patterns for laser annealing the Josephson junctions of the superconducting qubits.

The automated tuning process selects an initial Josephson junction or group of Josephson junctions of an initial superconducting qubit or quantum device in the quantum chip, and moves to the selected Josephson junction or group of Josephson junctions (block 1802). In particular, the control system 110 moves the X-Y-Z stage 142 to place the initial Josephson junction (or initial group of Josephson junctions) into the FOV of the microscope unit 130. In particular, the control system 110 moves the X-Y-Z stage 142 to place the initial Josephson junction (or group of Josephson junctions) into the FOV) of the microscope unit 130. The tuning process initiates control operations to cause the microscope unit and the probe unit to perform a focus and alignment process to ensure a proper focus to the focal plane and proper alignment of the target Josephson junction (or group of Josephson junctions) within the FOV of the microscope unit 130 for the purpose of performing an in-situ Josephson junction resistance measurement (block 1803). The focus ensures that the sample plane (e.g., the plane which contains the target Josephson junction) is at the focal plane (i.e., plane of focus) of the objective lens 137. The focus can be adjusted by adjusting the Z position of the X-Y-Z stage 142. The alignment to the Josephson junction (or group of Josephson junctions) can be performed using a machine learning pattern recognition process to align the Josephson junction (or group of Josephson junctions) to the center of the FOV.

Next, the tuning process proceeds to measure the junction resistance of the target Josephson junction (or group of Josephson junctions forming a Josephson-junction network) (block 1804). In particular, the tuning process measures an initial junction resistance Rᵢₙᵢₜᵢₐₗ of the Josephson junction (or group of Josephson junctions). In some embodiments, the electrical probes 144 are landed on the contact pads with a fixed displacement distance and overdrive to ensure proper contact (e.g., a stable, low resistance contact). In some embodiments, the electrical probes 144 are vertically moved downward to contact the tips of the electrical probes 144 to the contact pads on the quantum chip. In other embodiments, the positions of the electrical probes 144 remain fixed, and the Z position of the X-Y-Z stage 142 is moved upward so that the contact pads on the quantum chip are moved into contact with the tips of the electrical probes 144 (in which case a second focus and alignment step can be performed subsequent to the junction resistance measurement and prior to the initial laser annealing step as discussed below).

In some embodiments, an in-situ junction resistance measurement is performed by contacting the electrical probes with contact pads of the target Josephson junction (or group of Josephson junctions) and then applying a test DC voltage across the Josephson junction or group of Josephson junction to generate and measure a resulting DC current to determine a resistance of the Josephson junction or group of Josephson junctions. In some embodiments, as noted above, the junction resistance is determined using a 4-wire (Kelvin) probe resistance measurement operation, whereby a constant current is passed through the Josephson junction or Josephson junction network, and a resulting voltage across the Josephson junction or Josephson junction network is measured, wherein the resistance of the Josephson junction or Josephson junction network is determined based on the magnitude of the constant current and the measured voltage. In some or other embodiments, the resistance is determined using a 4-wire (Kelvin) probe resistance measurement operation, whereby a constant voltage is sourced across the Josephson junction or Josephson junction network, and the resulting current is measured, where the resistance of the Josephson junction or Josephson junction network is determined based on the magnitude of the constant voltage and the measured current. Moreover, in some embodiments, contact resistance and contact stability checks are initially performed, prior to performing the junction resistance measurement, to ensure that the contact resistance is below a given threshold, and to ensure that the contact between the electrical probe and the contact pads of the Josephson junction(s) are stable and not intermittent.

Next, the tuning process initiates control operations to cause the microscope unit 130 and the prober unit 140 to perform a focus and alignment process to ensure a proper focus to the focal plane and proper alignment of the target Josephson junction (or group of Josephson junctions) within the FOV of the microscope unit 130 for the purpose of performing a laser anneal operation (block 1805). The tuning process proceeds to determine a target combination of laser power, anneal time, and laser beam illumination pattern to configure the initial laser anneal operation (initial shot) in a manner that is sufficient to achieve a partial tuning of the Josephson junction(s) (block 1806) via either a positive resistance shift (increase junction resistance) or a negative resistance shift (decrease junction resistance), as needed, to shift the resistance of a Josephson junction by an initial tuning resistance shift

ΔRᵢₙᵢₜᵢₐₗ=F×ΔR_{target},

where

$$Δ {R}_{initial} = {R}_{initial \_ target} - {R}_{initial} .$$

For a positive resistance tuning,

R_{initial_target}=Rᵢₙᵢₜᵢₐₗ+ΔRᵢₙᵢₜᵢₐₗ.

On the other hand, for a negative resistance tuning,

R_{initial_target}=Rᵢₙᵢₜᵢₐₗ−ΔRᵢₙᵢₜᵢₐₗ.

In some embodiments, as noted above, the initial tuning factor F is selected to be F≅50% to appreciably tune the Josephson junction towards its target junction resistance R_{target}, while mitigating the risk of overshooting R_{target} on the initial laser annealing shot. Moreover, as noted above, the computed value of ΔRᵢₙᵢₜᵢₐₗ is utilized to determine a resistance shift percentage ΔR % which, in turn, can be used to determine a given combination of laser power, anneal time, and laser beam illumination pattern, to calibrate the initial laser tuning operation (initial shot) to achieve the initial tuning resistance shift ΔRᵢₙᵢₜᵢₐₗ (based on the measured initial junction resistance Rᵢₙᵢₜᵢₐₗ, and the computation

$$Δ R \% = \frac{Δ {R}_{initial}}{{R}_{initial}} \times 100 \% ) .$$

The tuning process performs the initial laser anneal operation (initial shot) on the given Josephson junction (or group of Josephson junctions) using the determined combination of laser power setting, anneal time, and laser beam illumination pattern, to achieve the desired amount of positive resistance shift to target, or negative resistance shift to target, for the initial shot (block 1807). After completion of the initial laser anneal operation for the given Josephson junction (or group of Josephson junctions), the tuning process determines whether there are any remaining Josephson junctions that need to be initially tuned to their respective initial tuning resistance shift ΔRᵢₙᵢₜᵢₐₗ using an initial laser anneal operation (block 1808). If there are one or more Josephson junctions that need to be to be tested (affirmative determination in block 1808), the tuning process selects a next Josephson junction (or group of Josephson junctions) of a next superconducting qubit to be tuned (return to block 1802) and repeats the laser tuning operations (repeat blocks 1803, 1804, 1805, 1806, and 1807).

On the other hand, if it is determined that there are no remaining Josephson junctions that need to be tuned to their respective initial tuning resistance shift ΔRᵢₙᵢₜᵢₐₗ using an initial laser anneal operation (negative determination in block 1808), the tuning process proceeds to tune each Josephson junction to its respective target junction resistance R_{target} using an adaptive tuning process (block 1808). At the completion of the adaptive tuning process, it is assumed that each Josephson junction comprises junction resistance which is at the target junction resistance R_{target} or near the target junction resistance R_{target} within some specified threshold percentage of the target junction resistance R_{target}, i.e.,

$$\frac{\vert {R}_{target} - {R}_{current} \vert}{{R}_{target}} \leq x ( e . g . , x = 0.003 ( or 0.3 \% ) ) .$$

With each Josephson junction having a junction resistance which is at or near its target junction resistance R_{target}, it is assumed that each corresponding superconducting qubit has been tuned successfully and within a corresponding bound of precision to its respective target transition frequency.

In some embodiments, an adaptive tuning process (block 1809) comprises an iterative laser tuning process for tuning the junction resistances of the Josephson junctions by implementing an asymptotic tuning methodology in which Josephson junctions of, e.g., qubits on a given multi-qubit device are adaptively and progressively tuned in an incremental manner to progressively shift junction resistances towards respective target junction resistances of the Josephson junctions. In some embodiments, adaptive and progressive tuning of a given Josephson junction is implemented by adaptively determining the anneal time (tₛₕₒₜ) for a given tuning iteration at a given laser power level based on a function of (i) an amount of resistance shift remaining (ΔR_{remaining}) to reach the target junction resistance, and (ii) a total amount of anneal time spent for previous laser anneal iterations applied to the Josephson junction.

For example, an exemplary function for determining an anneal time (tₛₕₒₜ) for a given “shot” at a given laser power level is expressed as:

$${t}_{shot} ( {N}_{A} ) = \frac{Δ {R}_{target} - Δ R}{Δ {R}_{target}} \cdot {\sum }_{i = 1}^{{N}_{A} - 1} {t}_{shot} ( i ) for [ {N}_{A} > 1 ] ,$$

where N_{A} denotes an anneal number (or “shot” number), where, as noted above, ΔR_{target} denotes a difference between a target junction resistance (R_{target}) of a given Josephson junction and an initial measured resistance (denoted Rᵢₙᵢₜᵢₐₗ) of the given Josephson junction before the initial anneal operation (at N_{A}=0), and where ΔR denotes a difference between Rᵢₙᵢₜᵢₐₗ and a currently measured junction resistance (denoted R_{current}) of the given Josephson junction, which is measured in a given iteration before applying the next “shot” based on the computed anneal time tₛₕₒₜ for the given iteration. In other words,

ΔR_{target}=R_{target}−Rᵢₙᵢₜᵢₐₗ,ΔR=R_{current}−Rᵢₙᵢₜᵢₐₗ,

and

ΔR_{remaining}=R_{target}−R_{current}.

In the context of an adaptive tuning process, the parameter R_{current} denotes a current junction resistance that is measured at the beginning of each successive iteration of the adaptive tuning process, and the computation tₛₕₒₜ is performed for each successive iteration of the adaptive tuning process to determine a target anneal time for performing the laser anneal operation for given iteration. As noted above, the laser power level that is used in each iteration is the laser power level that was initially selected to perform the initial laser annealing operation (block 1806, FIG. 18). Note also that the exemplary function for determining anneal time (tₛₕₒₜ) for a given shot is valid for both positive and negative resistance tuning. That is, the ratio of ΔR_{remaining} and ΔR_{target} is always positive regardless of the directionality of tuning, as long as the junction resistance has not yet reached its target value.

In the exemplary function for computing tₛₕₒₜ, the ratio

$$\frac{Δ {R}_{target} - Δ R}{Δ {R}_{target}} = \frac{Δ {R}_{remaining}}{Δ {R}_{target}}$$

provides a weight factor that represents a percentage of the amount of a remaining amount of resistance shift needed to reach the target junction resistance R_{target} of the given Josephson junction based on the total resistance shift needed to reach the target junction resistance R_{target} starting from the initial measured junction resistance Rᵢₙᵢₜᵢₐₗ of the given Josephson junction. In addition, the summation

$${\sum }_{i = 1}^{{N}_{A} - 1} {t}_{shot} ( i )$$

provides weight factor based on the sum total time of all anneal times (total amount of all determined tₛₕₒₜ times) of all previous “shots” applied to the given Josephson junction. It is to be noted that the exemplary function for tₛₕₒₜ provides a linear combination of weight factors based on a product of ΔR_{remaining} and the total historical anneal time. In other embodiments, a function for computing tₛₕₒₜ can be based on other parameters and/or based on a non-linear function of the parameters ΔR_{remaining} and the total historical anneal time and/or other parameters, depending on, e.g., the application and/or the tuning characteristics of the Josephson junction as determined based on the associated tuning calibration data obtained using the calibration techniques as discussed herein.

Based the exemplary parameters of the function tₛₕₒₜ, at a given iteration of the tuning process, if the measured junction resistance indicates that there is a relatively large amount of resistance shift still needed to reach the target junction resistance R_{target}, the determined anneal time, tₛₕₒₜ, will be weighted

$$( by the ratio \frac{Δ {R}_{remaining}}{Δ {R}_{target}} )$$

to be longer. On the other hand, if there is a relatively small amount of resistance shift needed to reach the target junction resistance R_{target}, the anneal time, tₛₕₒₜ, will be weighted

$$( by the ratio \frac{Δ {R}_{remaining}}{Δ {R}_{target}} )$$

to be shorter. As another example, if the summation

$${\sum }_{i = 1}^{{N}_{A} - 1} {t}_{shot} ( i )$$

at a given iteration (e.g., at a given N_{A}) of the tuning process indicates a relatively large total amount of annealing has been performed on the given Josephson junction, this provides an indication that the given Josephson junction is tuning slowly, so that the next anneal time, tₛₕₒₜ, will be weighted (by the sum total anneal time) to be relatively long. On the other hand, if the summation

$${\sum }_{i = 1}^{{N}_{A} - 1} {t}_{shot} ( i )$$

at a given iteration of the tuning process indicates a relatively small total duration of annealing has been performed on the given Josephson junction, this provides an indication that the given Josephson junction is tuning relatively fast, so that the next anneal time, tₛₕₒₜ, will be weighted (by the sum total anneal time) to be relatively short.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 1900 of FIG. 19 contains an example of an environment for the execution of at least some of the computer code (block 1926) comprising data processing and control algorithms for performing various operations such as laser annealing operations, imaging operations, machine learning pattern recognition operations, junction resistance measurement operations, tunning calibration operations, and other computer automated control and data processing operations as discussed herein for performing the various methods as shown and described, for example, in conjunction with FIGS. 1, 2, 3A, 3B, 4, 5A-5E, 6A, 6B, 7A-71, 10A, 10B, 11, 12A, 12B, 13A, 13B, 14A, 14B, and 15-18. In addition to block 1926, computing environment 1900 includes, for example, computer 1901, wide area network (WAN) 1902, end user device (EUD) 1903, remote server 1904, public cloud 1905, and private cloud 1906. In this embodiment, computer 1901 includes processor set 1910 (including processing circuitry 1920 and cache 1921), communication fabric 1911, volatile memory 1912, persistent storage 1913 (including operating system 1922 and block 1926, as identified above), peripheral device set 1914 (including user interface (UI), device set 1923, storage 1924, and Internet of Things (IoT) sensor set 1925), and network module 1915. Remote server 1904 includes remote database 1930. Public cloud 1905 includes gateway 1940, cloud orchestration module 1941, host physical machine set 1942, virtual machine set 1943, and container set 1944.

Computer 1901 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1930. As is well understood in the art of computer technology, and depending upon the technology, performance of a computer-implemented method may be distributed among multiple computers and/or between multiple locations. On the other hand, in this presentation of computing environment 1900, detailed discussion is focused on a single computer, specifically computer 1901, to keep the presentation as simple as possible. Computer 1901 may be located in a cloud, even though it is not shown in a cloud in FIG. 19. On the other hand, computer 1901 is not required to be in a cloud except to any extent as may be affirmatively indicated.

Processor set 1910 includes one, or more, computer processors of any type now known or to be developed in the future. Processing circuitry 1920 may be distributed over multiple packages, for example, multiple, coordinated integrated circuit chips. Processing circuitry 1920 may implement multiple processor threads and/or multiple processor cores. Cache 1921 is memory that is located in the processor chip package(s) and is typically used for data or code that should be available for rapid access by the threads or cores running on processor set 1910. Cache memories are typically organized into multiple levels depending upon relative proximity to the processing circuitry. Alternatively, some, or all, of the cache for the processor set may be located “off chip.” In some computing environments, processor set 1910 may be designed for working with qubits and performing quantum computing.

Computer readable program instructions are typically loaded onto computer 1901 to cause a series of operational steps to be performed by processor set 1910 of computer 1901 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1921 and the other storage media discussed below. The program instructions, and associated data, are accessed by processor set 1910 to control and direct performance of the inventive methods. In computing environment 1900, at least some of the instructions for performing the inventive methods may be stored in block 1926 in persistent storage 1913.

Communication fabric 1911 comprises the signal conduction paths that allow the various components of computer 1901 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 1912 is any type of volatile memory now known or to be developed in the future. Examples include dynamic type random access memory (RAM) or static type RAM. Typically, the volatile memory is characterized by random access, but this is not required unless affirmatively indicated. In computer 1901, the volatile memory 1912 is located in a single package and is internal to computer 1901, but, alternatively or additionally, the volatile memory may be distributed over multiple packages and/or located externally with respect to computer 1901.

Persistent storage 1913 is any form of non-volatile storage for computers that is now known or to be developed in the future. The non-volatility of this storage means that the stored data is maintained regardless of whether power is being supplied to computer 1901 and/or directly to persistent storage 1913. Persistent storage 1913 may be a read only memory (ROM), but typically at least a portion of the persistent storage allows writing of data, deletion of data and re-writing of data. Some familiar forms of persistent storage include magnetic disks and solid-state storage devices. Operating system 1922 may take several forms, such as various known proprietary operating systems or open source Portable Operating System Interface type operating systems that employ a kernel. The code included in block 1926 typically includes at least some of the computer code involved in performing the inventive methods.

Peripheral device set 1914 includes the set of peripheral devices of computer 1901. Data communication connections between the peripheral devices and the other components of computer 1901 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1923 may include components such as a display screen, speaker, microphone, wearable devices (such as goggles and smart watches), keyboard, mouse, printer, touchpad, game controllers, and haptic devices. Storage 1924 is external storage, such as an external hard drive, or insertable storage, such as an SD card. Storage 1924 may be persistent and/or volatile. In some embodiments, storage 1924 may take the form of a quantum computing storage device for storing data in the form of qubits. In embodiments where computer 1901 is required to have a large amount of storage (for example, where computer 1901 locally stores and manages a large database) then this storage may be provided by peripheral storage devices designed for storing very large amounts of data, such as a storage area network (SAN) that is shared by multiple, geographically distributed computers. IoT sensor set 1925 is made up of sensors that can be used in Internet of Things applications. For example, one sensor may be a thermometer and another sensor may be a motion detector.

Network module 1915 is the collection of computer software, hardware, and firmware that allows computer 1901 to communicate with other computers through WAN 1902. Network module 1915 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1915 are performed on the same physical hardware device. In other embodiments (for example, embodiments that utilize software-defined networking (SDN)), the control functions and the forwarding functions of network module 1915 are performed on physically separate devices, such that the control functions manage several different network hardware devices. Computer readable program instructions for performing the exemplary inventive methods can typically be downloaded to computer 1901 from an external computer or external storage device through a network adapter card or network interface included in network module 1915.

WAN 1902 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 1903 is any computer system that is used and controlled by an end user (for example, a customer of an enterprise that operates computer 1901), and may take any of the forms discussed above in connection with computer 1901. EUD 1903 typically receives helpful and useful data from the operations of computer 1901. For example, in a hypothetical case where computer 1901 is designed to provide a recommendation to an end user, this recommendation would typically be communicated from network module 1915 of computer 1901 through WAN 1902 to EUD 1903. In this way, EUD 1903 can display, or otherwise present, the recommendation to an end user. In some embodiments, EUD 1903 may be a client device, such as thin client, heavy client, mainframe computer, desktop computer and so on.

Remote server 1904 is any computer system that serves at least some data and/or functionality to computer 1901. Remote server 1904 may be controlled and used by the same entity that operates computer 1901. Remote server 1904 represents the machine(s) that collect and store helpful and useful data for use by other computers, such as computer 1901. For example, in a hypothetical case where computer 1901 is designed and programmed to provide a recommendation based on historical data, then this historical data may be provided to computer 1901 from remote database 1930 of remote server 1904.

Public cloud 1905 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1905 is performed by the computer hardware and/or software of cloud orchestration module 1941. The computing resources provided by public cloud 1905 are typically implemented by virtual computing environments that run on various computers making up the computers of host physical machine set 1942, which is the universe of physical computers in and/or available to public cloud 1905. The virtual computing environments (VCEs) typically take the form of virtual machines from virtual machine set 1943 and/or containers from container set 1944. It is understood that these VCEs may be stored as images and may be transferred among and between the various physical machine hosts, either as images or after instantiation of the VCE. Cloud orchestration module 1941 manages the transfer and storage of images, deploys new instantiations of VCEs and manages active instantiations of VCE deployments. Gateway 1940 is the collection of computer software, hardware, and firmware that allows public cloud 1905 to communicate through WAN 1902.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 1906 is similar to public cloud 1905, except that the computing resources are only available for use by a single enterprise. While private cloud 1906 is depicted as being in communication with WAN 1902, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1905 and private cloud 1906 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method, comprising:
performing a pattern recognition process to determine a geometry of a superconducting quantum device comprising one or more Josephson junctions;
determining, based on the geometry determined by the pattern recognition process, a laser beam illumination pattern for laser annealing the one or more Josephson junctions of the superconducting quantum device; and
configuring a laser microscope to generate the laser beam illumination pattern.

2. The method of claim 1, wherein determining the laser beam illumination pattern comprises:
determining a target thermal profile for laser annealing the one or more Josephson junctions of the superconducting quantum device; and
selecting a laser beam illumination pattern which corresponds to the target thermal profile.

3. The method of claim 2, wherein selecting a laser beam illumination pattern which corresponds to the target thermal profile, comprises:
accessing a database comprising the plurality of thermal profiles and corresponding laser beam illumination patterns;
matching a thermal profile in the database with the target thermal profile; and
selecting a laser beam illumination pattern in the database which corresponds to the matching thermal profile.

4. The method of claim 1, wherein determining the laser beam illumination pattern comprises:
accessing a database comprising a plurality of template device geometries and corresponding laser beam illumination patterns;
matching the determined geometry of the superconducting quantum device to a template device geometry in the database; and
selecting a laser beam illumination pattern in the database which corresponds to the matching template device geometry.

5. The method of claim 1, wherein configuring the laser microscope to generate the laser beam illumination pattern, comprises:
configuring the laser microscope to generate a collimated laser beam having a target beam diameter; and
configuring the laser microscope to select one of a plurality of different diffractive optical elements to place in an optical path of the collimated laser beam to split the collimated laser beam into a plurality of laser beams.

6. The method of claim 1, wherein configuring the laser microscope to generate the laser beam illumination pattern, comprises:
configuring the laser microscope to generate a collimated laser beam having a target beam diameter;
configuring the laser microscope to select one of a plurality of different spiral phase plates to place in an optical path of the collimated laser beam to generate an annular laser beam based on the collimated laser beam; and
configuring the laser microscope to select one of a plurality of different diffractive optical elements to place in an optical path of the annular laser beam to split the annular laser beam into a plurality of annular laser beams.

7. The method of claim 1, wherein configuring the laser microscope to generate the laser beam illumination pattern, comprises:
configuring the laser microscope to generate a collimated laser beam having a target beam diameter; and
configuring the laser microscope to select one of a plurality of different optical attenuation elements to place in an optical path of the collimated laser beam to adjust a laser illumination intensity of the collimated laser beam based on the selected optical attenuation element.

8. An apparatus, comprising:
a collimator configured to receive a laser beam through an optical fiber coupled to an optical source and to generate a collimated laser beam;
a switchable attenuator device comprising a plurality of attenuation elements, and configured to selectively position a given attenuation element in an optical path of the collimated laser beam to adjust a laser illumination intensity of the collimated laser beam based on the given attenuation element; and
a switchable diffractive optical element device comprising a plurality of diffractive optical elements, and configured to selectively position a given diffractive optical element in the optical path of the collimated laser beam to split the collimated laser beam into a plurality of laser beams.

9. The apparatus of claim 8, further comprising a switchable spiral phase plate device comprising a plurality of spiral phase plates with different topological charges, and configured to selectively position a given spiral phase plate in the optical path of the collimated laser beam to generate an annular laser beam with a given annular diameter and beam hole diameter based on the topological charge of the given spiral phase plate.

10. The apparatus of claim 8, further comprising a variable beam expander which is configured to adjust a diameter of the collimated laser beam.

11. The apparatus of claim 8, further comprising:
an objective lens;
a polarizing beam splitter which is configured to direct the plurality of laser beams generated by the given diffractive optical element to the objective lens which focusses the plurality of laser beams to generate a laser beam illumination pattern at a focal plane; and
a piezoelectric actuator device coupled to the polarizing beam splitter and configured to adjust an angle of the polarizing beam splitter to align the laser beam illumination pattern to one of a center of a field of view of the objective lens and a target device in the field of view of the objective lens.

12. The apparatus of claim 11, further comprising an imager configured to generate an image of a target device in a field of view of the objective lens to facilitate alignment of the target device in the field of view of the objective lens and alignment of the laser beam illumination pattern to the target device for laser annealing the target device.

13. The apparatus of claim 12, further comprising an electronic beam shutter that is configured to affect an exposure time for laser annealing the target device.

14. The apparatus of claim 8, further comprising components that are configured to monitor a power level of the collimated laser beam, where the components of the power monitor comprise a cleanup polarizer element to mitigate undesirable stray polarization, a beam sampler to pick-off a small fraction of the beam for sampling, and a power meter element to monitor the power level of the sampled collimated laser beam.

15. A method, comprising:
aligning a superconducting quantum device which comprises a geometry of one or more Josephson junctions, in a field of view of a laser microscope apparatus;
generating, by operation of the laser microscope apparatus, a laser beam illumination pattern based on the geometry of the one or more Josephson junctions of the superconducting quantum device;
adjusting, by operation of the laser microscope apparatus, an illumination intensity of the laser beam illumination pattern; and
exposing, by operation of the laser microscope apparatus, the superconducting quantum device with the laser beam illumination pattern for a given anneal time to laser anneal the one or more Josephson junctions of the superconducting quantum device.

16. The method of claim 15, wherein generating the laser beam illumination pattern based on the geometry of the one or more Josephson junctions of the superconducting quantum device, comprises generating a multi-spot laser beam illumination pattern that configured to concurrently laser anneal two or more Josephson junctions of the superconducting quantum device.

17. The method of claim 16, wherein the multi-spot laser beam illumination pattern comprises a plurality of annular laser beam spots.

18. The method of claim 15, wherein generating the laser beam illumination pattern based on the geometry of the one or more Josephson junctions of the superconducting quantum device comprises generating at least one annular laser beam spot that is aligned to surround at least one of the one or more Josephson junctions.

19. The method of claim 15, further comprising adjusting, by operation of the laser microscope apparatus, a beam width of a laser beam that is utilized to generate the laser beam illumination pattern.

20. The method of claim 15, further comprising selectively positioning, by operation of the laser microscope apparatus, one of a plurality of diffractive optical elements in an optical path of a laser beam to split the laser beam into a plurality of laser beams for generating the laser beam illumination pattern.
